(19) United States
(12) Patent Application Publication
(10) Pub. No.: US 2026/0052892 A1
(43) Pub. Date: Feb. 19, 2026

(54) DISPLAY MODULE AND ELECTRONIC DEVICE INCLUDING THE DISPLAY MODULE

(71) Applicant: Samsung Display Co., LTD., Yongin-si (KR)

(72) Inventors: GI-NA YOO, Yongin-si (KR); HYOMIN KIM, Yongin-si (KR); SANG MIN HONG, Yongin-si (KR)

(21) Appl. No.: 19/199,996

(22) Filed: May 6, 2025

(30) Foreign Application Priority Data
Aug. 16, 2024 (KR) 10-2024-0110007

(51) Int. Cl. H10K 59/80; H10K 50/15; H10K 59/122; H10K 59/35; H10K 59/38; H10K 102/00

(52) U.S. Cl. CPC H10K 59/8792; H10K 50/15; H10K 59/122; H10K 59/352; H10K 59/38; H10K 2102/351

(57) ABSTRACT

A display module includes a display panel that includes a first light-emitting element which overlaps a first pixel region and emits light of a first color, and a second light-emitting element which emits the light of the first color and overlaps a second pixel region spaced apart from the first pixel region on a plane, an anti-reflection layer that is disposed on the display panel and includes the first light-blocking layer, and an optical functional layer that is disposed on the anti-reflection layer and includes the second light-blocking layer. A first opening corresponding to the first pixel region and the second pixel region is defined in the first light-blocking layer, and a second opening overlapping the second pixel region and corresponding to the first opening is defined in the second light-blocking layer.

This application claims priority to Korean Patent Application No. 10-2024-0110007, filed on Aug. 16, 2024, and all the benefits accruing therefrom under 35 U.S.C. § 119, the content of which in its entirety is herein incorporated by reference.

### BACKGROUND

The present disclosure herein relates to a display module and an electronic device including the display module, and more particularly, to a display module that is driven with low power consumption and an electronic device including the display module.

Multimedia devices such as televisions, mobile phones, tablet computers, navigation systems, and game consoles include a display module in order to display a video. A display module may include an organic electroluminescence display panel. The organic electroluminescence display panel may include a light-emitting element, and the light-emitting element may emit light by recombination of electrons and holes. The organic electroluminescence display panel has rapid response times and the advantage of driving with low power consumption.

### SUMMARY

The present disclosure provides a display module having improvements in lifespan and reliability since the display module may be operated with low power consumption even when blocking light emitted at a high angle from screens with different viewing angles.

The present disclosure also provides an electronic device having improvements in display quality and reliability, and simultaneously having privacy protection.

An embodiment of the inventive concept provides a display module including a display panel, an anti-reflection layer disposed on the display panel and including a first light-blocking layer; and an optical functional layer disposed on the anti-reflection layer and including a second light-blocking layer, wherein the display panel includes a first light-emitting element which overlaps a first pixel region and emits light of a first color, and a second light-emitting element which overlaps a second pixel region that is spaced apart from the first pixel region on a plane and emits the light of the first color. First openings corresponding to the first pixel region and the second pixel region are defined in the first light-blocking layer, second openings overlapping the first pixel region and the second pixel region and corresponding to the first opening are defined in the second light-blocking layer, the first light-emitting element includes a first hole transport layer and a first emission layer disposed on the first hole transport layer, the second light-emitting element includes a second hole transport layer and a second emission layer disposed on the second hole transport layer, and the first hole transport layer has a (1-1)-st thickness smaller than a (2-1)-st thickness of the second hole transport layer.

In an embodiment, the second light-blocking layer may not overlap the first pixel region.

In an embodiment, the first emission layer may have a (1-2)-nd thickness greater than a (2-2)-nd thickness of the second emission layer.

In an embodiment, a sum of the (1-1)-st thickness and the (1-2)-nd thickness may be substantially equal to a sum of the (2-1)-st thickness and the (2-2)-nd thickness.

In an embodiment, a material included in the first hole transport layer may be the same as a material included in the second hole transport layer.

In an embodiment, a material included in the first emission layer may be the same as a material included in the second emission layer.

In an embodiment, the display panel may further include a pixel definition film in which a plurality of pixel openings corresponding to the first pixel region and the second pixel region is defined, and each of the first emission layer and the second emission layer maybe disposed within each of the plurality of pixel openings.

In an embodiment, the anti-reflection layer may further include a plurality of color filters corresponding to the first pixel region and the second pixel region, and the first light-blocking layer may separate the plurality of color filters from one another.

In an embodiment, the first light-emitting element and the second light-emitting element may be driven in a first mode, and the first light-emitting element may not be driven, and the second light-emitting element is driven, in a second mode having low reflectance compared to the first mode.

In an embodiment, the light of the first color may be red light or green light

In an embodiment, a sensor layer may be further included between the display panel and the anti-reflection layer.

In an embodiment of the inventive concept, a display module includes a first pixel group including a first light-emitting element that emits light of a first color and overlaps a first region, and a second pixel group including a second light-emitting element that emits the light of the first color and overlaps a second region that has a lower light transmittance for the light of the first color than the first region, wherein, the light of the first color is red light or green light, the first light-emitting element includes a first hole transport layer and a first emission layer that is disposed on the first hole transport layer, the second light-emitting element includes a second hole transport layer and a second emission layer that is disposed on the second hole transport layer, and a (1-1)-st thickness of the first hole transport layer is smaller than a (2-1)-st thickness of the second hole transport layer.

In an embodiment, a first thickness difference between the (2-1)-st thickness of the second hole transport layer and the (1-1)-st thickness of the first hole transport layer may range from about 30 Å to about 300 Å.

In an embodiment, the first region may include a (1-1)-st pixel region which emits red light, a (1-2)-nd pixel region which emits green light, and a (1-3)-rd pixel region which emits blue light, and the second region may include a (2-1)-st pixel region which emits red light, a (2-2)-nd pixel region which emits green light, and a (2-3)-rd pixel region which emits blue light.

In an embodiment, an area of the (1-1)-st pixel region on a plane may be relatively larger than an area of the (2-1)-st pixel region on the plane, an area of the (1-2)-nd pixel region on the plane may be relatively larger than an area of the (2-2)-nd pixel region on the plane; and an area of the (1-3)-rd pixel region on the plane may be relatively larger than an area of the (2-3)-rd pixel region on the plane.

In an embodiment, the first hole transport layer and the first emission layer may be each disposed corresponding to the (1-1)-st pixel region, and the second hole transport layer and the second emission layer may be each disposed corresponding to the (2-1)-st pixel region, or the first hole transport layer and the first emission layer may be each disposed corresponding to the (1-1)-st pixel region, and the hole transport layer and the second emission layer may be each disposed corresponding to the (2-1)-st pixel region.

In an embodiment, a hole injection layer disposed below the first hole transport layer and the second hole transport layer may be further included, wherein the hole injection layer may be commonly disposed in the (1-1)-st pixel region, the (1-2)-nd pixel region, and the (1-3)-rd pixel region.

In an embodiment, the hole injection layer may include a charge generating material.

In an embodiment of the inventive concept, an electronic device includes a display module, a window disposed on the display module, and a housing combined with the window and accommodating the display module, wherein the display module includes a display panel including a first light-emitting element that overlaps a first pixel region and emits light of a first color, and a second light-emitting element that overlaps a second pixel region spacing apart from the first pixel region on a plane and emits the light of the first color, an anti-reflection layer disposed on the display panel and including the first light-blocking layer, and an optical functional layer disposed on the anti-reflection layer and including the second light-blocking layer. First openings corresponding to the first pixel region and the second pixel region are defined in the first light-blocking layer, second openings overlapping the first pixel region and the second pixel region and corresponding to the first opening are defined in the second light-blocking layer, the first light-emitting element includes a first hole transport layer and a first emission layer disposed on the first hole transport layer, the second light-emitting element includes a second hole transport layer and a second emission layer disposed on the second hole transport layer, and a (1-1)-st thickness of the hole transport layer is smaller than a (2-1)-st thickness of the second hole transport layer.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a front view of an electronic device according to an embodiment of the inventive concept;

FIG. 1B is a perspective view of an electronic device according to an embodiment of the inventive concept;

FIG. 2 is a block view of an electronic device according to an embodiment of the inventive concept;

FIG. 3 is an exploded perspective view of the electronic device according to an embodiment of the inventive concept.

FIG. 4 is a cross-sectional view of a display module according to an embodiment of the inventive concept;

FIG. 5 is a plan view illustrating by magnifying a portion of a display module according to an embodiment of the inventive concept;

FIG. 6A is a cross-sectional view of a portion of a display module according to an embodiment of the inventive concept;

FIG. 6B is a cross-sectional view of another portion of the display module according to an embodiment of the inventive concept;

FIG. 7 is a plan view of a portion of a first light-blocking layer according to an embodiment of the inventive concept;

FIGS. 8A and 8B are each a plan view of a portion of a second light-blocking layer according to an embodiment of the inventive concept;

FIGS. 9A and 9B are cross-sectional views schematically illustrating a light-emitting element according to an embodiment of the inventive concept;

FIG. 10 is a cross-sectional view schematically illustrating light-emitting elements according to an embodiment of the inventive concept; and

FIG. 11A and FIG. 11B are cross-sectional views schematically illustrating light-emitting elements according to other embodiments of the inventive concept.

### DETAILED DESCRIPTION

As used herein, when an element (or region, layer part, or other element) is referred to as being “disposed on,” “connected to,” or “combined with” other elements, it means that the element may be directly disposed on/connected to/combined with other elements, or means that a third intervening element may be disposed therebetween.

Like reference numerals refer to like elements throughout. In some aspects, in the drawings, the thicknesses, proportions, and dimensions of the components are exaggerated for the purpose of effectively illustrating the technical content. The term “and/or” includes one or more combination that may be defined by associated components.

It will be understood that, although the terms first, second, and the like, may be used herein to describe various elements, these elements should not be limited by these terms. These terms are used to distinguish one element from another element. For example, a first element could be termed as a second element without departing from the scope of rights of the embodiments of the present disclosure. Similarly, the second element could be termed as the first element. The singular forms are intended to include the plural forms as well, unless the context clearly indicates otherwise in context.

In some aspects, the terms such as “under”, “below”, “above”, “on” are used for describing one element's relationship to another element as illustrated in the drawings. The terms have relative concepts, and will be described with respect to the directions illustrated in the drawings.

It will be further understood that the terms “including” or “having,” when used in this specification, specify the presence of stated features, numerals, steps, operations, components, parts, or the combination thereof, but are not intended to preclude, in advance, the presence or addition of one or more other features, numerals, steps, operations, components, parts, or the combination thereof.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within +30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and the inventive concept, and will not be interpreted in an idealized or overly formal sense unless expressly so defined herein.

The terms “part”, and “unit” means a software component or a hardware component, which performs a specific function. The hardware component may include, for example, a field-programmable gate array (FPGA) or an application-specific integrated circuit (ASIC). The software component may refer to executable code and/or data used by executable code in an addressable storage device. Therefore, the software components may be, for example, object-oriented software components, class components, and work components and may include processes, functions, attributes, procedures, subroutines, program code segments, drivers, firmware, microcode, circuits, data, databases, data structures, tables, arrays, or variables.

Hereinafter, embodiments of the inventive concept will be described with reference to the accompanying drawings.

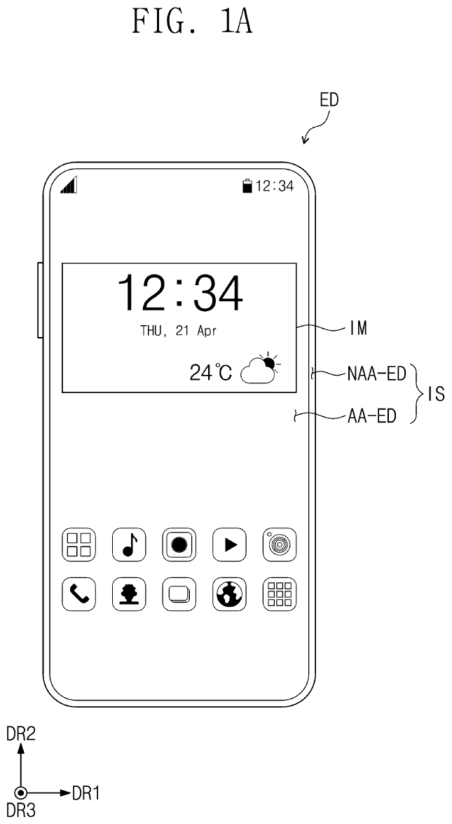

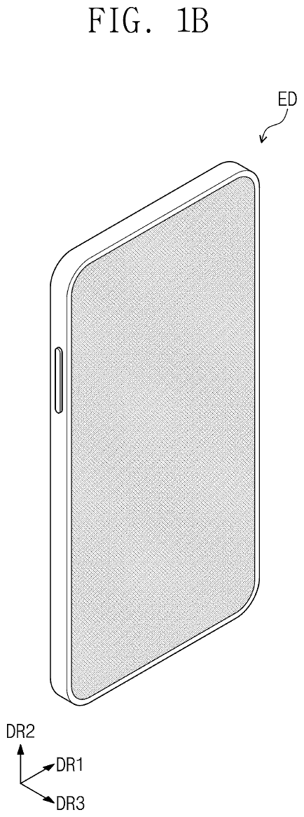

FIG. 1A is a front view of an electronic device ED according to an embodiment of the inventive concept. FIG. 1B is a perspective view of an electronic device ED according to an embodiment of the inventive concept.

Referring to FIG. 1A and FIG. 1B, the electronic device ED may be activated in response to an electrical signal. An electronic device ED according to various embodiments disclosed in the present document may be a device in different forms. The electronic device ED may include, for example, at least one among a mobile communication device (for example, a smartphone), a computer device, a mobile multimedia device, a mobile medical device, a camera, a wearable device, or an appliance device. In FIG. 1A and FIG. 1B, a mobile phone is provided as an example of an electronic device ED.

An electronic device ED may display a video IM on a display surface IS. The display surface IS on which the video IM is displayed may correspond to a front surface of the electronic device. The display surface IS of the electronic device ED may be classified into an active region AA-ED and a peripheral region NAA-ED. A video IM may be displayed in the active region AA-ED. The video IM may be displayed through the active region AA-ED. The active region AA-ED may include a plane defined by a first direction DR1 and a second direction DR2. The active region AA-ED may further include a curved surface that is bent from at least one side of the surface defined by the first direction DR1 and the second direction DR2.

In some cases, in FIG. 1A and FIG. 1B, and the following drawings, a first direction to a third direction DR1, DR2, and DR3 are illustrated. In some aspects, a direction, described in the present specification, indicated by each of the first direction DR1, the second direction DR2, and the third direction DR3 has a relative concept, which may be converted into other directions.

As used herein, the first direction DR1 and the second direction DR2 are perpendicular to each other, and the third direction DR3 is a normal direction to the plane defined by the first direction DR1 and the second direction DR2. Meanwhile, as used herein, a meaning of “on a plane” may mean a case when is viewed from the plane defined form the first direction DR1 and the second direction DR2. A thickness direction may refer to the third direction DR3 which is a normal direction to the plane defined by the first direction DR1 and the second direction DR2.

FIG. 1A may be a front view of the electronic device ED which operates in a first mode or second mode. FIG. 1B is a side perspective view of the electronic device ED which operates in a second mode. For example, the first mode may be a normal mode in which a screen is displayed at a first viewing angle, and the second mode may be a private mode in which a screen is displayed at a second viewing angle smaller than the first viewing angle. The first viewing angle and the second viewing angle may be defined as angles at which an image may be viewed without distortion of display quality with respect to a normal direction of the display surface IS.

Referring to FIG. 1A, in the first mode or the second mode, when viewing the electronic device ED from a direction parallel to the normal direction or the third direction DR3, images IM generated in the electronic device ED may be viewed from a user. In the second mode, when viewing the electronic device ED at an angle larger than the second angle, the images IM may not be viewed.

The second angle and luminescence at the second angle in the second mode may be variously set. In an example in which viewing the electronic device ED at an angle larger than the second viewing angle in the first mode, the user may view the images IM. For example, the second viewing angle may be about 45 degrees, and luminescence at about 45 degrees may be about 10% of maximum luminescence. Luminescence at about 45 degrees in the first mode may be about 20%. However, embodiments of the present disclosure are not limited thereto.

The electronic device ED may be selectively operated in at least one among the first mode displaying a screen at the first viewing angle and the second mode displaying a screen at the second viewing angle smaller than the first viewing angle. A mode change between the first mode and the second mode may be set by the user, or when a specific application is executed, the mode may be switched from the first mode to the second mode. For example, when executing an application, such as, for example, an application for an banking, or memo application, having a risk of leakages of personal information, the electronic device ED may switch from the first mode to the second mode.

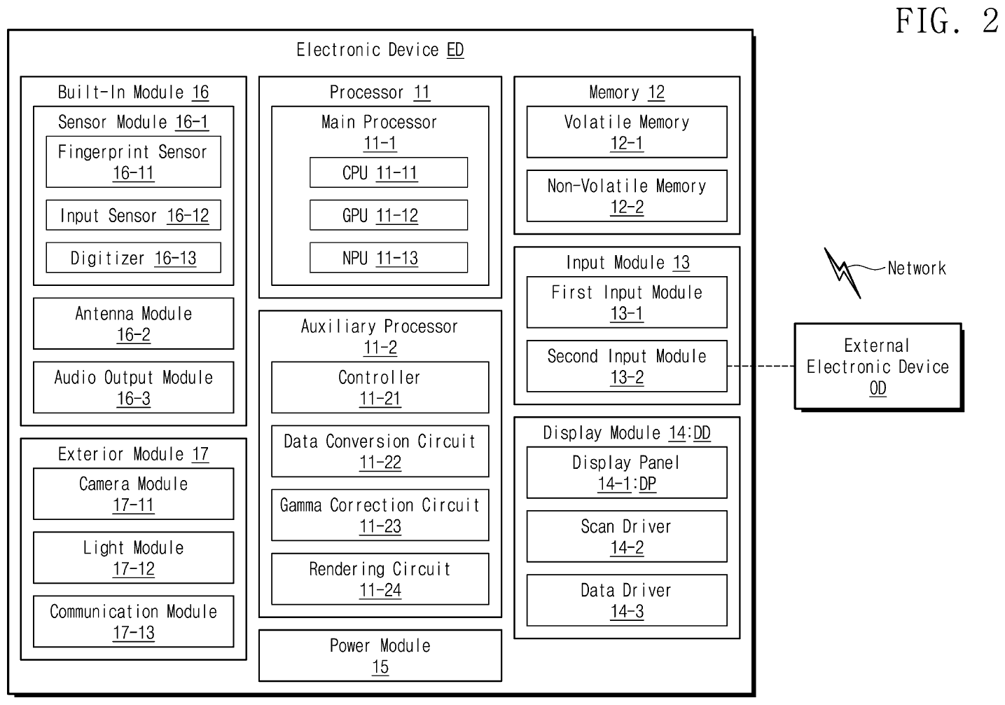

FIG. 2 is a block view of the electronic device ED according to an embodiment of the inventive concept.

The electronic device ED may output various information through a display module 14 within an operating system. In an example in which a processor 11 executes an application stored in a memory 12, the display module 14 provides an application information to the user through a display panel 14-1. The display module 14 in FIG. 2 may refer to a display module DD to be described later, and the display module 14-1 may refer to a display panel DP to be described later.

The processor 11 obtains an external input through an input module 13 or sensor module 16-1, and executes an application corresponding to the external input. In an example in which the user selects a camera icon displayed on the display panel 14-1, the processor 11 obtains the user's input through an input sensor 16-12 and activates a camera module 17-1. The processor 11 transmits, to the display module 14, video data corresponding to the captured image obtained through the camera module 17-1. The display module 14 may display the image corresponding to the captured image through the display panel 14-1.

In another example, when executing certification of personal information in the display panel 14, a fingerprint sensor 16-11 obtains input fingerprint information as input data. The processor 11 compares the input fingerprint information that is obtained through the fingerprint sensor 16-11 with certified data that is stored in a memory 12 and executes an application according to a compared result. The display module 14 may display, through the display module 14-1, information executed according to a logic of the application.

For still another example, when selecting a music streaming icon displayed on the display module 14, the processor 11 obtains the user's input through an input sensor 16-12, and activates a music streaming application stored in the memory 12. In the music streaming application, when a command of music playback is entered, the processor 11 activates an audio output module 16-3, and provides audio information corresponding to the command for music playback.

Hitherto, operations of the electronic device ED were briefly described. Hereinafter, components of the electronic device ED will be described in detail. Some components of the electronic device ED to be described later may be integrated and provided as one body and one component may be divided and provided into two or more components.

Referring to FIG. 2, the electronic device ED may communicate with an external electronic device OD via a network (e.g., short-range wireless communication network, or long-range wireless communication network). According to an embodiment, the electronic device ED may include a processor 11, a memory 12, an input module 13, a display module 14, a power module 15, an embedded module 16, and an external module 17. According to an embodiment, at least one of the above-described components may be omitted or one or more other components may be added in the electronic device ED. According to an embodiment, some components (e.g., a sensor module 16-1, an antenna module 16-2, or an audio output module 16-3) among the above-described components may be integrated into another component (e.g., a display module 14).

The processor 11 may control at least one different components (e.g., hardware or software component) of the electronic device ED connected to the processor 11 by activating a software, and may perform various data processing or calculations. According to an embodiment, as at least a portion of data processing or calculations, the processor 11 may store a command or data, which is received from another component (e.g., an input module 13, a sensor module 16-1, or a communication module 17-3), in a volatile memory 12-1, process the stored command or data in the volatile memory 12-1, and the result data may be stored in a non-volatile memory 12-2.

The processor 11 may include a main processor 11-1 and an auxiliary processor 11-2. The main processor 11-1 may include one or more among a central processing unit (CPU) 11-1 and an application processor (AP). The main processor 11-1 may further include any one or more among a graphic processing unit (GPU) 11-12, a communication processor (CP), and an image signal processor (ISP). The main processor 11-1 may further include a neural processing unit (NPU) 11-13. The neural processing unit may be a processor specified in a process of an artificial intelligence model, which may be generated through machine learning. The artificial intelligence model may include a plurality of artificial neural network layers. The artificial intelligence network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-networks, or a combination of two or more thereof. However, embodiments of the present disclosure are not limited thereto. The artificial intelligence model may additionally or generally include a software structure in addition to a hardware structure. At least two among the above-described processing units and processors may be implemented as an integrated component (e.g., a single chip), or may be each implemented as an independent component (e.g., a plurality of chips).

The auxiliary processor 11-2 may include a controller 11-21. The controller 11-21 may include an interface conversion circuit and a timing control circuit. The controller 11-21 receives a video signal from the main processor 11-1 and outputs video data by converting a data format of the video signal such that the data format matches an interface specification of the display module 14. The controller 11-21 may output various types of control signals associated with driving the display module 14.

The auxiliary processor 11-2 may further include a data conversion circuit 11-22, a gamma correction circuit 11-23, a rendering circuit 11-24, and the like. The data conversion circuit 11-22 may receive video data from the controller 11-21, compensate for the video data so as to display the video at desired luminescence depending on characteristics of the electronic device ED, the user's set and the like, or may convert the video data for reducing a power consumption, a residue compensation, or the like. The gamma correction circuit 11-23 may convert video data, gamma reference voltage, or the like such that the video displayed on the electronic device ED has desired gamma properties. The rendering circuit 11-24 may receive video data from the controller 11-21 and may render the video data considering pixel alignments of the display panel 14-1 applied to the electronic device ED, and the like. At least one among the data conversion circuit 11-22, the gamma correction circuit 11-23, and the rendering circuit 11-24 may be integrated into another component (e.g., the main processor 11-1 or the controller 11-21). At least one among the data conversion circuit 11-22, the gamma correction circuit 11-23, and the rendering circuit 11-24 may also be integrated into a data driver 14-3 to be described later.

The memory 12 may store various data, input data or output data of a command related thereto, which are used by at least one component (e.g., the processor 11 or the sensor module 16-1). The memory 12 may include at least one among a volatile memory 12-1 and a non-volatile memory 12-2.

The input module 13 may receive, from an outside of the electronic device (e.g., the user or external electronic device OD), a command or data to be used for a component (e.g., a processor 11, a sensor module 16-1, or an audio output module 16-3) of the electronic device ED.

The input module 13 may include a first input module 13-1 to which a command or data is entered from the user, and a second input module 13-2 to which a command or data is entered from the external electronic device OD. The first input module 13-1 may include a mic, a mouse, a keyboard, a key (e.g., button) or a pen (e.g., a passive pen, or active pen). The second input module 13-2 may support a designated protocol that may connect to the external electronic device OD via a wired or wireless mean. According to an embodiment, the second module 13-2 may include a high definition multimedia interface (HDMI), an universal serial bus (USB) interface, an SD card interface, or an audio interface. The second input module 13-2 may include a connector which may the external electronic device OD, such as, for example, a HDMI connector, a USB connector, an SD card connector, or an audio connector (e.g., a headphone connector), physically connected.

The display module 14 provides visual information to the user. The display module 14 may include a display panel 14-1, a scan driver 14-2, and a data driver 14-3. The display module 14 may further include a window, a chassis, or a bracket for protecting the display panel 14-1.

The display panel 14-1 may include a liquid display panel, an organic electroluminescence display panel, or an inorganic electroluminescence display panel, and the types of the display panel 14-1 are not particularly limited. The display panel 14-1 may be a rigid type, or a flexible type capable of being rolled or folded. The display module 14 may further include a supporter supporting the display panel 14-1, a bracket, a heat sink, and the like. The display panel 14-1 will be described in detail, hereinafter, in FIG. 4 and below.

The scan driver 14-2 may be mounted on the display panel 14-1 as a driving chip. In some aspects, the scan driver 14-2 may be integrated in the display panel 14-1. For example, the scan driver 14-2 may include an amorphous silicon (ASG) TFT gate driver circuit, a low temperature polycrystalline silicon (LTPS) TFT gate driver circuit, or an oxide semiconductor TFT gate driver circuit (OSG). The scan driver 14-2 may receive a control signal from the controller 11-21 and output scan signals to the display panel 14-1 in response to the control signal.

The display panel 14-1 may further include a luminous driver. The luminous driver outputs a luminous control signal to the display panel 14-1 in response to the control signal received from the controller 11-21. The luminous driver may be formed distinctly from the scan driver 14-2, or may be integrated into the scan driver 14-2.

The data driver 14-3 receives a control signal from the controller 11-21, and converts video data to an analog voltage (e.g., data voltage) to output the data voltage on the display panel 14-1 in response to the control signal/The data driver 14-3 may be integrated into another component (e.g., controller 11-21). In the above-described controller 11-21, functions of an interface conversion circuit and a timing control circuit may be integrated into the data driver 14-3.

The display module 14 may further include a luminous driver, a voltage generation circuit, and the like. The voltage generation circuit may output various voltages for driving the display panel 14-1.

The power module 15 supplies power to components of the electronic device ED. The power module 15 may include a battery that charges the power module. The battery may include a primary battery which is non-rechargeable, a secondary battery which is rechargeable, or a fuel cell. The power module 15 may include a power management integrated circuit (PMIC). PMIC supplies the ultimate power to each of the above-described modules and modules to be described later. The power module 15 may include a member for wireless power transmission and reception, which is electrically connected to the battery. The member for wireless power transmission and reception may include a plurality of antenna elements in a coil shape.

The electronic device ED may further include a built-in module 16 and an external module 17. The built-in module 16 may include a sensor module 16-1, an antenna module 16-2, and an audio output module 16-3. The external module 17 may include a camera module 17-1, a light module 17-2, and a communications module 17-3.

The sensor module 16-1 may detect an input by the user's body or an input by a pen of a first input module 13-1, and may generate an electrical signal or a data value corresponding to the input. The sensor module 16-1 may include at least one among a fingerprint sensor 16-11, an input sensor 16-12, and a digitizer 16-13.

The fingerprint sensor 16-11 may generate a data value corresponding to the user's fingerprint. The fingerprint sensor 16-11 may include any one among an optical or capacitive fingerprint sensor.

The input sensor 16-12 may generate a data value corresponding to coordinate information of the input by a user's body or a pen. The input sensor 16-12 generates a data value of a input-dependent change in capacitance. The input sensor 16-12 may detect an input by a passive pen or may transmit or receive data with an active pen.

The input sensor 16-12 may also measure a biometric signal such as, for example, blood pressure, hydration level, or body fat percentage. In an example in which the user touches the sensor layer or a sensing panel with a body part and stays still for a certain time, the input sensor 16-12 detects a biometric signal on the basis of variations in electric field caused by body contact and may output user's desired information to the display module 14.

The digitizer 16-13 may generate a data value corresponding to coordination information due to a pen input. The digitizer 16-13 generates, as a data value, electromagnetic variations caused by the input. The digitizer 16-13 may detect an input by a passive pen, or may transmit and receive data with an active pen.

At least one among the fingerprint sensor 16-11, the input sensor 16-12, and the digitizer 16-13 may be implemented as a sensor layer 200 (see FIG. 4) formed on the display panel 14-1 through continuous processes. The fingerprint sensor 16-11, the input sensor 16-12, and the digitizer 16-13 may be disposed on the display panel 14-1, and any one (e.g., the digitizer 16-13) among the fingerprint sensor 16-11, the input sensor 16-12, and the digitizer 16-13, may be disposed below the display panel 14-1.

At least two or more among the fingerprint sensor 16-11, the input sensor 16-20, and the digitizer 16-13 may be formed to be integrated into one sensing panel through the same process. When integrated into one sensing panel, the sensing panel may be disposed between the display panel 14-1 and a window that is disposed above the display panel 14-1. According to an embodiment, the sensing panel may be disposed on the window, and a position of the sensing panel is not particularly limited.

At least one among the fingerprint sensor 16-11, the input sensor 16-12, and the digitizer 16-13 may be built in the display panel 14-1. That is, at least one among the fingerprint sensor 16-11, the input sensor 16-12, and the digitizer 16-13 may be simultaneously formed through a process forming elements (e.g., light-emitting element, transistor, or the like) included in the display panel 14-1.

Besides, a sensor module 16-1 may generate an electrical signal or data value corresponding to an internal state or external state of the electronic device ED. The sensor module 16-1 may further include, for example, a gesture sensor, a gyroscope sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or a light sensor.

The antenna module 16-2 may include at least one antenna for transmitting signals or power to the outside or receiving from the outside. According to an embodiment, the communication module 17-3 may transmit or receive signals to or from the external electronic devices via the antenna appropriate for a communication scheme. An antenna pattern of the antenna module 16-2 may be integrated into one component (e.g., display panel 14-1, input sensor 16-12, or the like) of the display module 14.

The audio output module 16-3 may be a device for outputting audio signals to the outside of the electronic device ED, and may include, for example, a speaker used for a general use such as, for example, playing multimedia or playing a recording file, and a receiver exclusively used for receiving incoming call. According to an embodiment, the receiver may be formed integrally with or separately from the speaker. An output pattern of the audio output module 16-3 may be integrated into the display module 14.

The camera module 17-1 may capture still images and videos. According to an embodiment, the camera module 17-1 may include one or more lens, an image sensor, or a image signal processor. The camera module 17-1 may further include an infrared camera capable of measuring user existence, user's whereabouts, user's gaze, and the like.

The light module 17-2 may provide light. The light module 17-2 may include a luminous diode or Zenon lamp. The light module 17-2 may operate in conjunction with the camera module 17-1 or independently.

The communication module 17-3 may support establishing a wired or wireless communication channel between the electronic device ED and the external electronic device OD, and may support performing communication via the established communication channel. The communication module 17-3 may include any one or include all of a wireless communication module such as, for example, a cellular communication module, a short-range wireless communication module, or a global navigation satellite system (GNSS) communication module; or a wired communication module such as, for example, a local area network (LAN) communication module; and a power line communication module. The communication module 17-3 may communicate with the external electronic device OD via a short-range communication network such as, for example, a Bluetooth, a WiFi direct or infrared data association (IrDA), or a long-range communication network, such as, for example, a cellular network, the Internet, or a computer network (e.g., LAN or WAN). These above-described various types of communication modules 17-3 may be implemented as a single chip, or each may be implemented as a separate chip.

The input module 13, the sensor module 16-1, the camera module 17-1, and the like may be utilized in controlling operation of the display module 14 in conjunction with the process 11.

The processor 11 outputs, based on input data which is received from the input module 13, a command or data to the display module 14, the audio output module 16-3, the camera module 17-1, or the light module 17-2. For example, the processor 11 may output by generating video data corresponding to the input data applied through a mouse or active pen to, thereby outputting the data in the display module 14. Alternatively, the processor 11 may generate command data corresponding to the input data, thereby outputting the data in the camera module 17-1 or light module 17-2. The processor 11 may convert an operating mode of the electronic device ED into a low-power mode or a sleep mode, thereby capable of reducing power consumption in the electronic device ED when no input data has been received for a predetermined time from the input module 13.

The processor 11 outputs, based on sensing data received from the sensor module 16-1, a command or data to the display module 14, the audio output module 16-3, the camera module 17-1 or the light module 17-2. For example, the processor 11 may compare certification data applied by the fingerprint sensor 16-11 with certification data stored in the memory 12, and then may execute an application according to the compared result. The processor 11 may execute a command or output corresponding video data to the display module 14 on the basis of the sensing data detected by the input sensor 16-12 or the digitizer 16-13. In an example in which the temperature sensor is included in the sensor module 16-1, the processor 11 may receive temperature data for the measured temperature by the sensor module 16-1, and luminance correction for video data may be further carried out on the basis of the temperature data.

The processor 11 may receive measurement data of user existence, user's whereabouts, user's gaze, and the like from the camera module 17-1. The processor 11 may further carry out luminance correction on the video data and the like on the basis of the measurement data. For example, the processor 11 determines the user existence through the input from the camera module 17-1, and may output, on the display module 14, video data with corrected luminance via a data conversion circuit 11-22 or gamma correction circuit 11-23.

Some components among the above-described components may be mutually interconnected and communicate signals (e.g., commands or data) with each other via an inter-peripheral communication scheme such as, for example, a bus, a general purpose input/output (GPIO), a serial peripheral interface (SPI), or a ultra path interconnect link. The processor 11 may communicate with the display module 14 via a predetermined interface, may use, for example, any one among the above-described communication scheme. An embodiment of the inventive concept is not limited to the above-described communication scheme.

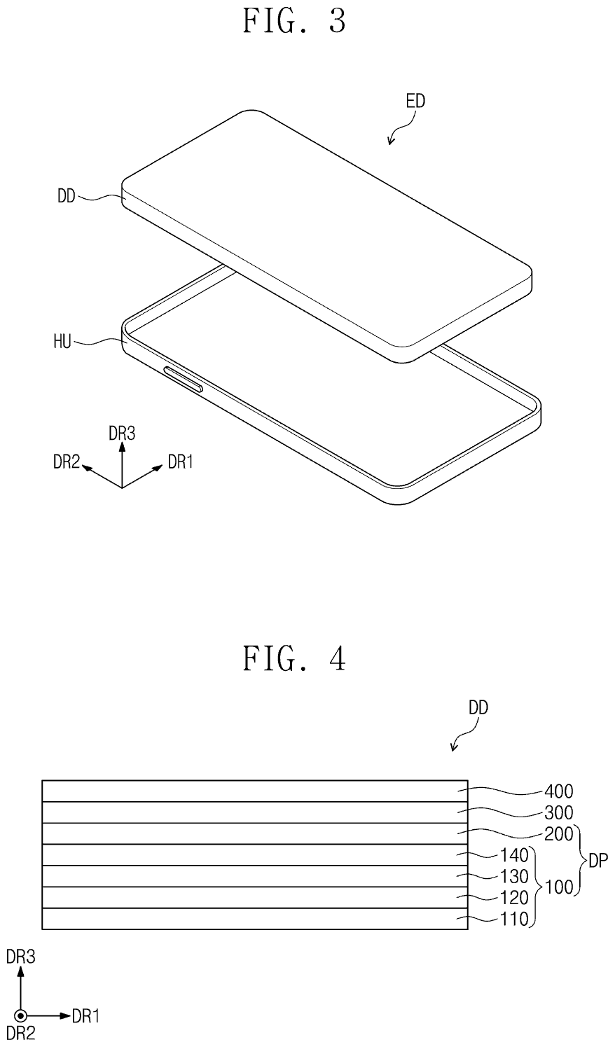

FIG. 3 is an exploded perspective view of the electronic device ED according to an embodiment of the inventive concept.

Referring to FIG. 3, the electronic device ED according to an embodiment may include a display module DD and a housing HU disposed below the display module DD.

A front surface of the display module DD may include a display region corresponding to the above-described active region AA-ED (see FIG. 1A), and a non-display region corresponding to the above-described peripheral region NAA-ED (see FIG. 1A). In the electronic device ED according to an embodiment, the display module DD may be accommodated within the housing HU. A window (not illustrated) and the housing HU may be combined to constitute an appearance of the electronic device ED.

FIG. 4 is a cross-sectional view of the display module DD according to an embodiment of the inventive concept.

The display module DD may include a display panel DP, an anti-reflection layer 300, and an optical functional layer 400. However, this is an example, and the display module DD may include no optical functional layer 400.

The display panel DP may include a display layer 100 and a sensor layer 200.

The display layer 100 may include a base layer 110, a circuit layer 120, a light-emitting element layer 130, and an encapsulation layer 140. The display layer 100 may be a component substantially generating a video. The display layer 100 may be a luminous-type display layer, and for example, the display layer 100 may be an organic electroluminescence display layer, an inorganic electroluminescence display layer, an organic-inorganic electroluminescence display, a quantum dot display layer, a micro LED display layer, or a nano LED display layer.

The base layer 110 may be a member providing a base surface on which a circuit layer 120 is disposed. The base layer 110 may be a glass substrate, a metal substrate, a silicon substrate, a polymer substrate, etc. However, embodiments of the present disclosure are not limited thereto, and the base layer 110 may be an inorganic layer, an organic layer, or a composite material layer.

The circuit layer 120 may be disposed on the base layer 110. The circuit layer 120 may include an insulation layer, a semiconductor layer, a conductive pattern, signal lines, or the like. An insulation layer, a semiconductor pattern, a conductive layer may be formed on the base layer 110 by methods such as, for example, coating, and deposition, and subsequentially the insulation layer, the semiconductor layer and the conductive layer may be selectively patterned by repeating a photolithography process multiple time. Thereafter, the semiconductor pattern, the conductivity pattern, and the signal lines included in the circuit layer 120 may be formed.

The light-emitting element layer 130 may be disposed on the circuit layer 120. The light-emitting element layer 130 may include a light-emitting element. For example, the light-emitting element layer 130 may include an organic light-emitting material, an inorganic light-emitting material, an organic-inorganic light-emitting material, a quantum dot, a quantum rod, a micro LED, or a nano LED.

The encapsulation layer 140 may be disposed on the light-emitting element layer 130. The encapsulation layer 140 may protect the light-emitting element layer 130 from foreign substances such as, for example, moisture, oxygen, and dust particles.

The sensor layer 200 may detect an external input applied from the outside. The external input may be a user's input. The user's input may include various types of external input such as, for example, touch by user's body part, light, heat, a pen, or pressure. The sensor layer 200 may be referred to as a sensor, an input detecting layer, or an input detecting panel. The sensor layer 200 may be formed through a continuous process with the display layer 100, and thus may be disposed directly on the display layer 100. However, an embodiment of the inventive concept is not particularly limited thereto. For example, the sensor layer 200 may also be combined with the display layer 100 via an adhesive layer. The adhesive layer may include a commercial adhesive, or pressure-sensitive adhesive.

The anti-reflection layer 300 may be disposed on the sensor layer 200. The anti-reflection layer 300 may reduce a reflectance of the display device DD to external light incident from the outside. The anti-reflection layer 300 may be directly disposed on the sensor layer 200. However, an embodiment of the inventive concept is not particularly limited thereto, and an adhesive member may also be disposed between the anti-reflection layer 300 and the sensor layer 200.

An optical functional layer 400 may be disposed on the anti-reflection layer 300. The optical functional layer may serve to cover the anti-reflection layer 300. In some aspects, the optical functional layer 400 may serve as a planarization layer. Light emitted from the light-emitting element layer 130 should pass through the optical functional layer 400, and thus the optical functional layer 400 may contain optically transparent materials.

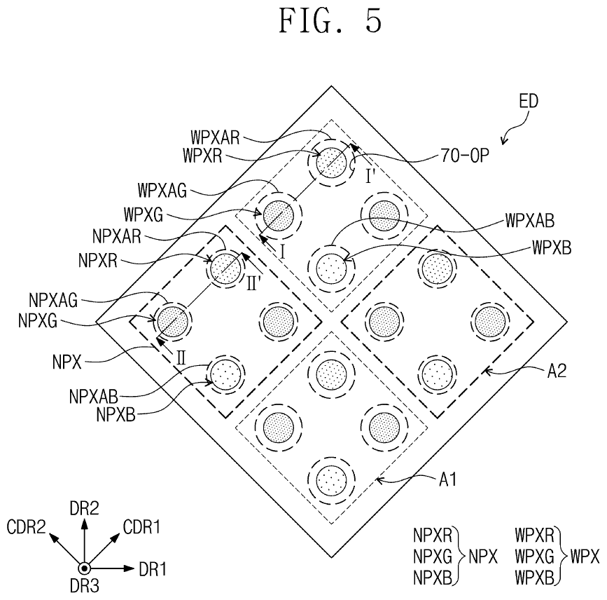

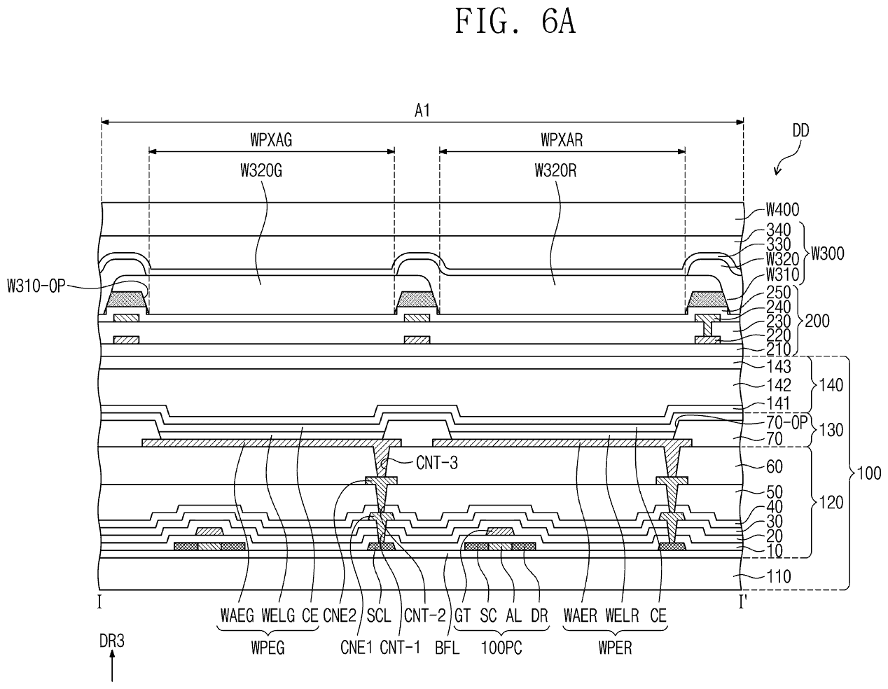

FIG. 5 is a plan view magnifying a portion of the display module DD according to an embodiment of the inventive concept.

Referring to FIG. 5, the display module DD may include a first pixel group WPX and a second pixel group NPX. The first pixel group WPX may include pixels having a relatively wide viewing angle, and the second pixel group NPX may include pixels having a relatively narrow viewing angle.

Each of the first pixel group WPX and the second pixel group NPX may be activated or deactivated depending on a first mode or a second mode. The first mode may be a normal mode in which the first pixel group WPX and the second group NPX may be all activated. The second mode may be a private mode in which the first pixel group WPX is deactivated and only the second group NPX is activated.

The first pixel group WPX may include a (1-1)-st pixel WPXR, a (1-2)-nd pixel WPXG, and a (1-3)-rd pixel WPXB. The second pixel group NPX may include a (2-1)-st pixel NPXR, a (2-2)-nd pixel NPXG, and a (2-3)-rd pixel NPXB. Each of the first pixel group WPX and the second pixel group NPX may include one red pixel, one blue pixel, and two green pixels. The (1-1)-st pixel WPXR and the (2-1)-st pixel NPXR may provide first light, the (1-2)-nd pixel WPXG and the (2-2)-nd pixel NPXG may provide second light different from the first light, and the (1-3)-rd pixel WPXB and the (2-3)-rd pixel NPXB may provide third light different from the first light and the second light. In an embodiment, the first light, second light, and third light may be red, green, and blue, respectively. However, this is an example, and the number and light-providing type of each pixel may be different from the embodiment.

The first pixel group WPX and the second pixel group NPX may be alternately repeatedly arranged in diagonal directions CDR1 and CDR2. The (1-1)-st pixel WPXR and the (1-3)-rd pixel WPXB in the first pixel group WPX may be alternately arranged one by one in the second direction DR2. In some aspects, the (2-1)-st pixel NPXR and the (2-3)-rd pixel NPXB in the second pixel group NPX may be alternately arranged one by one in the second direction DR2. The (1-2)-nd pixel WPXG of the first pixel group WPX may be arranged in the diagonal directions CDR1 and CDR2 of the (1-1)-st pixel WPXR and the (1-3)-rd pixel WPXB. The (2-2)-rd pixel NPXG of the second pixel group NPX may be arranged in the diagonal directions CDR1 and CDR2 of the (2-1)-st pixel (NPXR) and the (2-3)-rd pixel NPXB.

The first diagonal direction CDR1 may be a direction between the first direction DR1 and the second direction DR2, and the second diagonal direction CDR2 may be a direction between an opposite direction of the first direction DR1 and the second direction DR2. However, the arrangement relationships, illustrated in FIG. 4, between the (1-1)-st to (1-3)-rd pixels WPXR, WPXG, and WPXB and the (2-1)-st to (2-3)-rd pixels NPXR, NPXG, and NPXB are provided as examples for illustrative purposes, and the arrangement relationships, between the (1-1)-st to (1-3)-rd pixels WPXR, WPXG, and WPXB and the (2-1)-st to (2-3)-rd pixels NPXR, NPXG, and NPXB are not particularly limited thereto.

The display region of the display module DD may include a first region A1 and a second region A2. The first region A1 may be defined as a region in which one first pixel group WPX is disposed, and the second region A2 may be defined as a region in which one second pixel group NPX is disposed.

In the display region of the display module DD, the first region A1 and the second region A2 may be arranged in a plurality. The first regions A1 may be separately arranged along the first direction DR1 and the second direction DR2. The second regions A2 may be separately arranged along the first direction DR1 and the second direction DR2. According to the present inventive concept, the first regions A1 and the second regions A2 may be alternately arranged along the first diagonal direction CDR1 and the second diagonal direction CDR2. The first regions A1 and the second regions A2, may each be defined as a rhombus shape on a plane.

According to an embodiment, four second regions A2 different from each other may be adjacently disposed in the first diagonal direction CDR1 and the second diagonal direction CDR2 with respect to one first region A1, and, four second regions A1 different from each other may be adjacently disposed in the first diagonal direction CDR1 and the second diagonal direction CDR2 with respect to one second region A2.

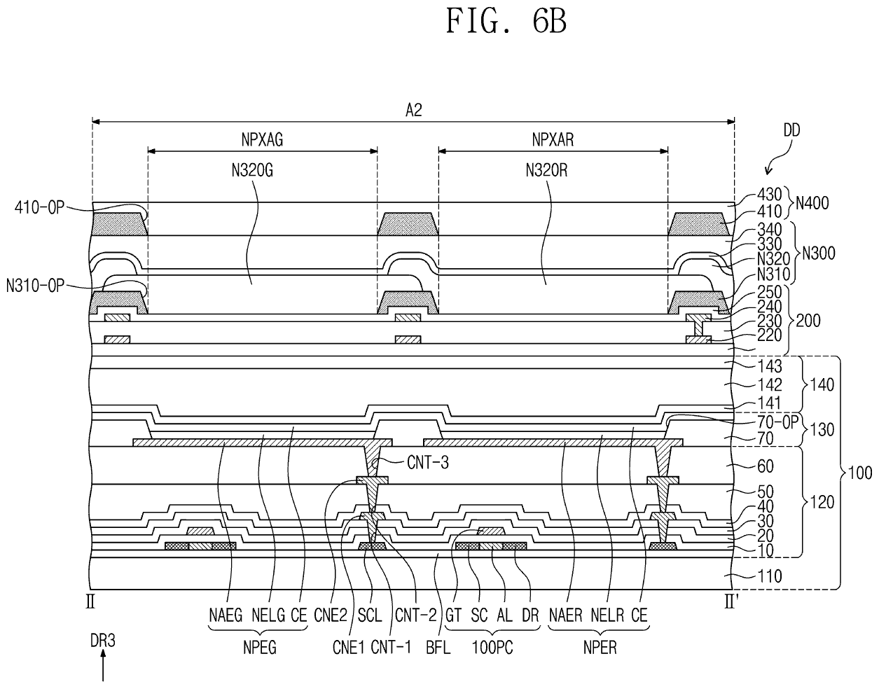

The first region A1 may include first pixel regions WPXAG, WPXAR, and WPXAB. The first pixel regions WPXAG, WPXAR, and WPXAB may include a (1-1)-st pixel region WPXAR, a (1-2)-nd pixel region WPXAG, and a (1-3)-rd pixel region WPXAB. The (1-1)-st pixel region WPXAR may be defined as a region in which light provided by the (1-1)-st pixel WPXR is viewed to the user, the (1-2)-nd pixel region WPXAG may be defined as a region in which light provided by the (1-2)-rd pixel WPXG is viewed to the user, and the (1-3)-rd pixel region WPXAB may be defined as a region in which light provided by the (1-3)-nd pixel WPXB is viewed to the user. The (1-1)-st pixel region WPXAR, the (1-2)-nd pixel region WPXAG, and the (1-3)-rd pixel region WPXAB may be each a region providing red light, green light, and blue light. The first pixel regions WPXAG, WPXAR, and WPXAB may be defined by a (1-1)-st opening W310-OP to be described in FIG. 6A.

The second region A2 may include second pixel regions NPXAG, NPXAR, and NPXAB. The second pixel regions NPXAG, NPXAR, and NPXAB may include a (2-1)-st pixel region NPXAR, a (2-2)-nd pixel region NPXAG, and a (2-3)-rd pixel region NPXAB. The (2-1)-st pixel region NPXAR may be defined as a region in which light provided by the (2-1)-st pixel NPXR is viewed to the user, the (2-2)-nd pixel region NPXAG may be defined as a region in which light provided by the (2-2)-rd pixel NPXG is viewed to the user, and the (2-3)-rd pixel region NPXAB may be defined as a region in which light provided by the (2-3)-nd pixel NPXB is viewed to the user. The (2-1)-st pixel region NPXAR, the (2-2)-nd pixel region NPXAG, and the (2-3)-rd pixel region NPXAB may be each a region providing red light, green light, and blue light. The second pixel regions NPXAG, NPXAR, and NPXAB may be defined by a (1-2)-nd opening N310-OP or second opening N410-OP to be described in FIG. 6B.

Each of the first pixel regions WPXAG, WPXAR, and WPXAB and the second pixel regions NPXAG, NPXAR, and NPXAB may have a circular shape. However, each shape of the first pixel regions WPXAG, WPXAR, and WPXAB and the second pixel regions NPXAG, NPXAR, and NPXAB is not limited thereto. For example, the first pixel regions WPXAG, WPXAR, and WPXAB and the second pixel regions NPXAG, NPXAR, and NPXAB may each have various shapes on a plane, such as, for example, a rectangle, a polygon, an ellipse, a triangle, or an irregular figure.

Each area of the first pixel regions WPXAR, WPXAG, and WPXAB may be larger than each area on a plane of the second pixel regions NPXAR, NPXAG, and NPXAB corresponding thereto. The (1-1)-st pixel region WPXAR may have a larger area than an area of the (2-1)-st pixel region NPXAR, the (1-2)-nd pixel region WPXAG may have a larger area than an area of the (2-2)-nd pixel region NPXAG, and the (1-3)-rd pixel region WPXAB may have a larger area than an area of the (2-3)-rd pixel region NPXAB. The first pixel regions WPXAR, WPXAG, and WPXAB defined in the first region A1 may have a larger area than an area of the second pixel regions NPXAR, NPXAG, and NPXAB defined in the second region A2. Therefore, the first region A1 may have greater light transmittance than light transmittance of the second region A2. In the present specification, the wording “light transmittance of the first region A1” may mean an amount ratio of light provided by the first light-emitting elements WPER and WPEG, which will be described later, to light reaching a surface IS (see FIG. 1A) in the first region A1, and the wording “light transmittance of the second region A2” may mean an amount ratio of light provided by the second light-emitting elements NPER and NPEG, which will be described later, to light reaching a surface IS (see FIG. 1A) in the second region A2.

FIG. 6A is a cross-sectional view illustrating a portion of the display module DD according to an embodiment of the inventive concept. FIG. 6A is a cross-sectional view of the display module DD according to an embodiment of the inventive concept taken along line I-I′ of the first pixel group WPX illustrated in FIG. 4.

Referring to FIG. 6A, at least one inorganic layer is formed on a top surface of the base layer 110. The inorganic layer may include at least one among aluminum oxide, titanium oxide, silicon oxide, silicon nitride, silicon oxynitride, zirconium oxide, and hafnium oxide. The inorganic layer may be formed in multiple layers. The multiple inorganic layers may form a barrier layer and/or a buffer layer. In the present embodiment, the display layer 100 is illustrated to include a buffer layer BFL.

The buffer layer BFL may improve adhesion between the base layer 110 and a semiconductor pattern. The buffer layer BFL may include at least one silicon oxide, silicon nitride, and silicon oxynitride. For example, the buffer layer BFL may include a structure in which a silicon oxide layer and a silicon nitride layer are alternately stacked.

A semiconductor pattern may be disposed on the buffer layer BFL. The semiconductor pattern may include polysilicon. However, embodiments of the present disclosure are not limited thereto, and the semiconductor pattern may also include amorphous silicon, low-temperature polycrystalline silicon, or oxide semiconductor.

FIG. 6A illustrates a portion of the semiconductor pattern, and the semiconductor pattern may be further disposed in other regions. The semiconductor pattern may be arranged over the pixels according to the specific rule. The semiconductor pattern may have different electrical properties depending on whether being doped or not. The semiconductor pattern may include a first conductive region having high conductivity and a second conductive region having low conductivity. The first conductive region may be doped with a n-type dopant, or a p-type dopant. A p-type transistor may include a doping region doped with a p-type dopant, and a n-type transistor may include a doping region doped with a n-type dopant. The second conductive region may be an undoped region, or a doped region at a lower concentration than the first conductive region.

The conductivity of the first conductive region is greater than the conductivity of the second conductive region, and the first conductive region may substantially serve as an electrode or as a signal line. The second conductive region may substantially correspond to an active region (or channel) of a transistor. In other words, a portion of the semiconductor pattern may be an active region of the transistor, another portion may be a source or a drain of the transistor, and still another portion may be a connection electrode or a connection signal line.

Exch pixel may include a pixel circuit and a light-emitting element. The pixel circuit may include a plurality of transistors and at least one capacitor. In FIG. 6A, a transistor 100PC is illustrated as an example of the plurality of transistors.

A source region SC, an active region AL, and a drain region DR of the transistor 100PC may be formed from the semiconductor pattern. The source region SC and the drain region DR may each be extended on a cross-section from the active region AL to opposite directions. In FIG. 6A, a portion of a connection signal line SCL formed from the semiconductor pattern is illustrated. Although not additionally illustrated, the connection signal line SCL may be connected to the drain region DR of the transistor 100PC on a plane.

A first insulation layer 10 may be disposed on the buffer layer BFL. The first insulation layer 10 may commonly overlap a plurality of pixels, and may cover the semiconductor pattern. The first insulation layer 10 may be an inorganic layer and/or organic layer, and may have a single- or multi-layered structure. The first insulation layer 10 may include at least one among aluminum oxide, titanium oxide, silicon oxide, silicon nitride, silicon oxynitride, zirconium oxide, and hafnium oxide. In the present embodiment, the first insulation layer 10 may be a single layer of silicon oxide. In addition to the first insulation layer 10, an insulation layer of a circuit layer 120 to be described later may be an inorganic layer and/or organic layer, and may have a single- or multi-layered structure. The inorganic layer may include at least one among the above-described materials, but is not limited thereto.

A gate GT of the transistor 100PC is disposed on the first insulation layer 10. The gate GT may be a portion of a metal pattern. The gate GT overlaps an active region AL. During a doping process of the semiconductor pattern, the gate GT may be serve as a mask.

A second insulation layer 20 may be disposed on the first insulation layer 10, and may cover the gate GT. The second insulation layer 20 may commonly overlap pixels. The second insulation layer 20 may be an inorganic layer and/or organic layer, and may have a single- or multi-layered structure. The second insulation layer 20 may include at least one among silicon oxide, silicon nitride, and silicon oxynitride. In the present embodiment, the second insulation layer 20 may have a multi-layered structure including a silicon oxide layer and a silicon nitride layer.

A third insulation layer 30 may be disposed on the second insulation layer 20. The third insulation layer 30 may have a single- or multi-layered structure. For example, the third insulation layer 30 may have a multi-layered structure including a silicon oxide layer and a silicon nitride layer.

A first connection electrode CNE1 may be disposed on the third insulation layer 30. The first connection electrode CNE1 may be connected to a connection signal line SCL via a contact hole CNT-1 penetrating the first, second and third insulation layers 10, 20, and 30.

A fourth insulation layer 40 may be disposed on the third insulation layer 30. The fourth insulation layer 40 may be a single layer of silicon oxide. A fifth insulation layer 50 may be disposed on the fourth insulation layer 40. The fifth insulation layer 50 may be an organic layer.

A second connection electrode CNE2 may be disposed on the fifth insulation layer 50. The second connection electrode CNE2 may be connected to the first connection electrode CNE1 via a contact hole CNT-2 penetrating the fourth insulation layer 40, and the fifth insulation layer 40 and 50.

A sixth insulation layer 60 may be disposed on the fifth insulation layer 50, and may cover the second connection electrode CNE2. The sixth insulation layer 60 may be an organic layer.

A light-emitting element layer 130 may be disposed on the circuit layer 120. The light-emitting element layer 130 may include first light-emitting elements WPER and WPEG. The first light-emitting elements WPER and WPEG may overlap the first pixel regions WPXAR and WPXAG. Each of the first light-emitting elements WPER and WPEG may include an organic light-emitting material, an inorganic light-emitting material, an organic-inorganic light-emitting material, a quantum dot, a quantum rod, and a micro LED, or a nano LED. Hereinafter, the inventive concept will be described through an embodiment in which the first light-emitting elements WPER and WPEG are each an organic light-emitting element, but is not particularly limited thereto.

The first light-emitting elements WPER and WPEG may include a (1-1)-st light-emitting element WPER included in the (1-1)-st pixel WPXR (see FIG. 5) and a (1-2)-nd light-emitting element WPEG included in the (1-2)-nd pixel WPXG (see FIG. 5). In some embodiments, although not illustrated in FIG. 6A, the first light-emitting elements may further include a (1-3)-rd light-emitting element WPEB included in the (1-3)-rd pixel WPXB (see FIG. 5). A structure on a cross-section of the (1-3)-rd light-emitting element may be substantially the same as a structure on a cross-section of the (1-1)-st light-emitting element WPER or the (1-2)-nd light-emitting element WPEG included in the (1-2)-nd pixel WPXG. However, the structure on a cross-section of the (1-3)-rd light-emitting element is not limited thereto, and, hereinafter, description for the (1-3)-rd light-emitting element is omitted.

The (1-1)-st light-emitting element WPER may include a (1-1)-st pixel electrode WAER, a (1-1)-st emission layer WELR, and a common electrode CE. The (1-2)-nd light-emitting element WPEG may include a (1-2)-nd pixel electrode WAEG, a (1-2)-nd emission layer WELG, and a common electrode CE. The common electrode CE included in the (1-1)-st light-emitting element WPER and the (1-2)-nd light-emitting element WPEG may be provided in any shape. The (1-1)-st pixel electrode WAER and the (1-2)-nd pixel electrode WAEG may be referred to as a first electrode, and the common electrode CE may be referred to as a second electrode.

The (1-1)-st pixel electrode WAER and the (1-2)-nd pixel electrode WAEG may be disposed on a sixth insulation layer 60. The (1-1)-st pixel electrode WAER and the (1-2)-nd pixel electrode WAEG may be connected to the second connection electrode CNE2 via a contact hole CNT-3 that penetrates the sixth insulation layer 60.

A pixel definition film 70 may be disposed on the sixth insulation layer 60, and may cover a portion of the (1-1)-st pixel electrode WAEG, and the (1-2)-nd pixel electrode WAEG. In the pixel definition film 70, a pixel opening 70-OP is defined. The pixel opening 70-OP of the pixel definition film 70 exposes at least one portion of the (1-1)-st pixel electrode WAER and the (1-2)-nd pixel electrode WAEG.

The first emission layers WELR and WELG may be disposed within the pixel opening 70-OP. The first emission layers WELR and WELG may be individually patterned for each pixel. The first emission layers WELR and WELG individually patterned may each emit different light from each other. The (1-1)-st emission layer WELR may be disposed within the pixel opening 70-OP overlapping the (1-1)-st pixel region WPXAR, and the (1-2)-nd emission layer WELG may be disposed within the pixel opening 70-OP overlapping the (1-2)-nd pixel region WPXAG. However, embodiments of the present disclosure are not limited thereto, and unlike what illustrated in FIG. 6A, the first emission layers WELR and WELG may be connected to each other to be commonly included in the plurality of light-emitting elements. In this case, the first emission layers WELR and WELG may provide blue light or white light.

The second electrode CE may be disposed on the first emission layers WELR and WELG. The second electrode CE may have any shape, and may be commonly included in a plurality of pixels.

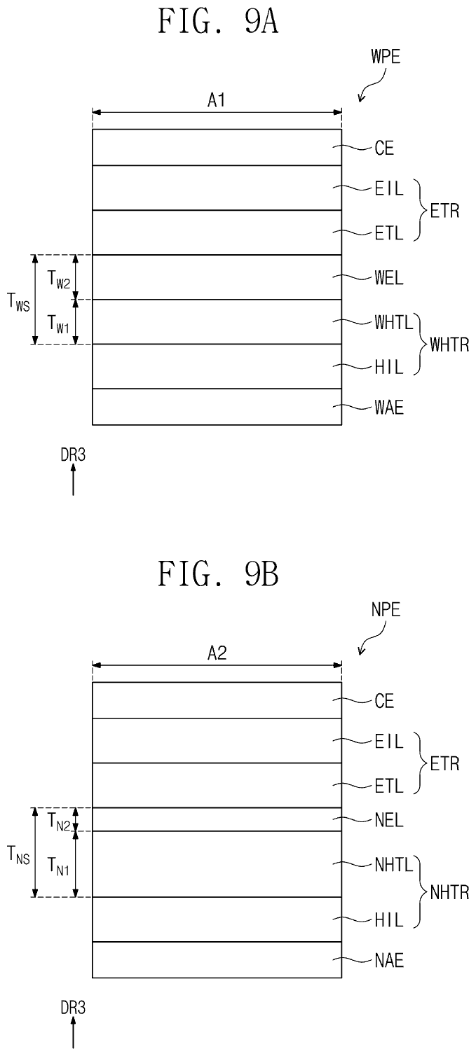

A hole control layer may be disposed between the first electrodes WAER and WAEG and the first emission layers WELR and WELG. The hole control layer may include a hole transport layer, and may further include a hole injection layer. An electron control layer may be disposed between the first emission layers WELR and WELG and the second electrode CE. The electron control layer may include an electron transport layer and may further include an electron injection layer. The hole control layer and the electron control layer may be commonly formed in a plurality of pixels using an open mask or inkjet process. The specific descriptions for a stacking structure of the first light-emitting element will be described in FIG. 9A and the following drawings.

The encapsulation layer 140 may be disposed on the light-emitting element layer 130. The encapsulation layer 140 may include a first inorganic layer 141, an organic layer 142, and a second inorganic layer 143, which are sequentially stacked, but layers constituting the encapsulation layer 140 are not limited thereto. The first and second inorganic layers 141 and 143 may protect the light-emitting element layer 130 from moisture and oxygen and the organic layer 142 may protect the light-emitting element layer 130 from foreign substances such as, for example, dust particles. The first and the second inorganic layers 141 and 143 may include a silicon nitride layer, a silicon oxynitride layer, a silicon oxide layer, a titanium oxide layer, an aluminum oxide layer, etc. The organic layer 142 may include an acryl-based organic layer, but is not particularly limited.

The sensor layer 200 may be disposed on the display layer 100. The sensor layer 200 may be referred to as a sensor, an input detection layer, or an input detection panel. The sensor layer 200 may include a sensor base layer 210, a first sensor conductive layer 220, a intermediate insulation layer 230, a second sensor conductive layer 240, and a sensor cover layer 250.

The sensor base layer 210 may be directly disposed on the display layer 100. The sensor base layer 210 may be an inorganic layer including at least any one among silicon nitride, silicon oxynitride, and silicon oxide. Alternatively, the sensor base layer 210 may be an organic layer including an epoxy resin, an acryl resin or an imide-based resin. The sensor base layer 210 may have a single-layered structure or may have a multi-layered structure stacked along the third direction DR3.

The first sensor conductive layer 220 and the second sensor conductive layer 240 may each have a single-layered structure, or may have a multi-layered structure stacked along the third direction DR3.

The conductive layer having a single-layered structure may include a metal layer or transparent conductive layer. The metal layer may contain molybdenum (Mo), silver (Ag), titanium (Ti), copper (Cu), aluminum (Al), or an alloy thereof. The transparent conductive layer may include transparent conductive oxides such as, for example, indium tin oxide, indium zinc oxide, zinc oxide or indium zinc tin oxide. Besides, the transparent conductive layer may include a conductive polymer such as, for example, poly(3,4-ethylenedioxythiophene) (PEDOT), a metal nano wire, graphene, or the like.

The conductive layer having a multi-layered structure may include metal layers. The metal layers may have a structure of, for example, a three-floor structure of titanium/aluminum/titanium. The conductive layer having a multi-layered structure may include at least one metal layer and at least one transparent conductive layer.

The intermediate insulation layer 230 may be disposed between a first sensor conductive layer 220 and a second sensor conductive layer 240. The intermediate insulation layer 230 may include an inorganic film. The inorganic film may contain at least one among aluminum oxide, titanium oxide, silicon oxide, silicon nitride, silicon oxynitride, zirconium oxide, and hafnium oxide.

Alternatively, the intermediate insulation layer 230 may include an organic film. The organic film may contain at least any one among an acryl-based resin, a methacryl-based resin, a polyisoprene, a vinyl-based resin, an epoxy-based resin, a urethane-based resin, a cellulose-based resin, a siloxane-based resin, a polyimide-based resin, a polyamide-based resin and a perylene-based resin.

A sensor cover layer 250 may be disposed on the intermediate insulation layer 230, and may cover the second sensor conductive layer 240. The second sensor conductive layer 240 may include a conductive pattern. The sensor cover layer 250 may cover a conductive pattern, and reduce or eliminate possibility of damage generation during a continuous process. The sensor cover layer 250 may include an inorganic material. For example, the sensor cover layer 250 may include silicon nitride, but is not particularly limited thereto. In an embodiment of the inventive concept, the sensor cover layer 250 may be also omitted.

A anti-reflection layer W300 may be disposed on the sensor layer 200. The anti-reflection layer W300 may include a first light-blocking layer W310, a plurality of color filters W320, an inorganic layer 330, and a planarization layer 340.

The first light-blocking layer W310 may be commonly disposed in the first region A1 and the second region A2 (see FIG. 6B). The first light-blocking layer W310 may be disposed overlapping the conductive pattern of the second sensor conductive layer 240. The sensor cover layer 250 may be disposed between the first light-blocking layer 310 and the second sensor conductive layer 240. The first light-blocking layer W310 may prevent external light from being reflected by the second sensor conductive layer 240.

A material constituting the first light-blocking layer W310 is not particularly limited as long as the material absorbs light. The first light-blocking layer W310 may be a layer having a black color, and in an embodiment, the first light-blocking layer W310 may include a black coloring ingredient. The black coloring ingredient may include a black dye and a black pigment. The black coloring ingredient may contain carbon black, a metal such as, for example, chrome, or an oxide thereof.

A plurality of first openings W310-OP may be defined in the first light-blocking layer W310. The first openings W310-OP may respectively correspond to the first pixel regions WPXAR and WPXAG. The first openings W310-OP may be defined by a side wall of the first light-blocking layer W310. The first openings W310-OP may each have relatively larger area than an area of the pixel opening 70-OP corresponding thereto. However, embodiments of the present disclosure are not limited thereto.

The plurality of color filters W320 may include a (1-1)-st color filter W320R and a (1-2)-nd color filter W320G disposed in the first region A1. The (1-1)-st color filter W320R and the (1-2)-nd color filter W320G may each be disposed within an opening W130-OP defined by the first region A1. The (1-1)-st color filter W320R may transmit light emitted from the (1-1)-st light-emitting element WPER, and the (1-2)-nd color filter W320G may transmit light emitted from the (1-2)-nd light-emitting element WPEG. Although not illustrated, the plurality of color filters W320 may further include a (1-3)-rd color filter overlapping the (1-3)-rd pixel WPXB (see FIG. 5).

In an embodiment of the inventive concept, the inorganic layer 330 may be disposed on the first color filters 320. The inorganic layer 330 may be formed in a shape covering the first color filters 320. Therefore, the first color filters 320 and the first light-blocking layer 310 may be protected from moisture and oxygen. The inorganic layer 330 may include a silicon nitride layer, a silicon oxynitride layer, a silicon oxide layer, a titanium oxide layer, or aluminum oxide layer, etc. The inorganic layer is illustrated in FIG. 6A, but this is an embodiment, and the inorganic layer 330 may be omitted.

A planarization layer 340 may cover the first light-blocking layer W310 and the plurality of color filter W320. The planarization layer 340 may include an organic layer, and a planarized surface may be provided on a top surface of the planarization layer 340

In an embodiment of the inventive concept, an optical functional layer W400 may be disposed on the anti-reflection layer W300. For example, the optical functional layer W400 may include an over-coating layer. Therefore, the anti-reflection layer W300 may be protected from the outside. However, this is an example, and the optical functional layer W400 may be omitted.

FIG. 6B is a cross-sectional view illustrating another portion of the display module DD according to an embodiment of the inventive concept. FIG. 6B is a cross-sectional view of the display module DD taken along line II-II′ of the second pixel group NPX illustrated in FIG. 5. FIG. 6B will mainly explain differences from FIG. 6A.

FIG. 6A described previously is a cross-sectional view including the first pixel group WPX that has a relatively wide viewing angle, and FIG. 6B to be described later is a cross-sectional view including the second pixel group NPX that has a relatively narrow viewing angle. The base layer 110, the circuit layer 120, the encapsulation layer 140, and the sensor layer 200 of the display layer 100, which are commonly illustrated in FIG. 6A and FIG. 6B, are substantially the same, and thus descriptions for the same will be omitted.

Referring to FIG. 6B, the light-emitting element layer 130 may include second light-emitting elements NPER and NPEG. The second light-emitting elements NPER and

NPEG may overlap the second pixel regions NPXAR and NPXAG.

The second light-emitting elements NPER and NPEG may include: a (2-1)-st light-emitting element NPER included in the (2-1)-st pixel NPXR (see FIG. 5); and a (2-2)-nd light-emitting element NPEG included in the (1-2)-nd pixel NPXG (see FIG. 5). In some embodiments, although not illustrated in FIG. 6B, the second light-emitting elements NPER and NPEG may further include a (2-3)-rd light-emitting element included in the (2-3)-rd pixel NPXB (see FIG. 5). A structure on a cross-section of the (2-3)-rd light-emitting element may be substantially the same as a structure of the (2-1)-st light-emitting element NPER on a cross-section or a structure of the (2-2)-nd light-emitting element NPEG on a cross-section. However, the structure of the (2-3)-rd light-emitting element on a cross-section is not limited thereto, and, hereinafter, descriptions for the (2-3)-rd light-emitting element will be omitted.

The anti-reflection layer N300 may include a first light-blocking layer N310, a plurality of color filters N320, an inorganic layer 330, and a planarization layer 340.

The anti-reflection layer N300 may include a first light-blocking layer N310 in which a plurality of first openings N310-OP is defined. The first openings N310-OP may correspond to each of first pixel regions WPXAR and WPXAG. The first openings N310-OP may be defined by a side wall of the first light-blocking layer N310. The first openings N310-OP may have a relatively large area compared to the pixel openings 70-OP corresponding thereto. However, embodiments of the present disclosure are not limited thereto.

An area of the first openings W310-OP (see FIG. 6A) overlapping the first region A1 (see FIG. 6A) may be larger than an area of the first openings N310-OP overlapping the second region A2. Therefore, an amount of light that is emitted by the second light-emitting elements NPER and NPEG and may be viewed to the user may be smaller than an amount of light that is emitted by the first light-emitting elements WPER and WPEG (see FIG. 6A) and may be viewed to the user.

The plurality of color filters N320 may include a (2-1)-st color filter N320R and a (2-2)-nd color filter N320G, which are disposed on the second region A2. Each of the (2-1)-st color filter N320R and the (2-2)-nd color filter N320G may be disposed within an opening N130-OP defined in the second region A2. The (2-1)-st color filter N320R may transmit light emitted by the (2-1)-st light-emitting element NPER, and the (2-2)-nd color filter N320G may transmit light emitted by the (2-2)-nd light-emitting element NPEG. Although not illustrated, the plurality of color filter N320 may further include a (2-3)-rd color filter overlapping the (2-3)-rd pixel NPXB (see FIG. 5).

In an embodiment of the inventive concept, the optical functional layer N400 may include a second light-blocking layer 410 and an over-coating layer 430.

The second light-blocking layer 410 may be disposed on the anti-reflection layer N300, and may be disposed to surround the second pixel regions NPXAR and NPXAG. The second light-blocking layer 410 may be formed using the substantially same material for the first light-blocking layer N310 of the anti-reflection layer N300. The second light-blocking layer 410 may prevent reflection for the external light, and may contain a black component absorbing light.

In the second light-blocking layer 410, a plurality of second openings 410-OP may be defined. The second openings 410-OP may correspond to each of the second pixel regions NPXAR and NPXAG. The second openings 410-OP may correspond to the first openings N310-OP. The second openings 410-OP may be defined by a side wall of the second light-blocking layer 410. The second openings N310-OP may have a relatively large area on a plane compared to the pixel opening 70-OP corresponding thereto. However, embodiments of the present disclosure are not limited thereto, and, as applicable, the second openings 410-OP may have smaller area on a plane than the pixel opening 70-OP.

The second openings 410-OP may have substantially the same area on a plane compared to the first openings N310-OP corresponding thereto. In some embodiments, as used herein, the wording “substantially the same” includes a case where differences exist within the margin of error that occurs during processing, despite having the same design, in addition to a case where a thickness of the component and the like are physically completely identical. However, embodiments of the present disclosure are not limited thereto, and, as applicable, the second openings 410-OP may have a larger area than the first openings N310-OP. Therefore, the second pixel regions NPXAR and NPXAG may be defined by the second opening 410-OP. Alternatively, the second openings 410-OP may have a smaller area than the first openings N310-OP, and thus the second pixel regions NPXAR and NPXAG may be also defined by the first opening N310-OP.

Compared FIG. 6B with the above-described FIG. 6A, the second pixel group NPX (see FIG. 5) may be driven in both of a first mode, which is a normal mode, and a second mode, which is a private mode. In some embodiments, the first pixel group WPX (see FIG. 5) may be not driven in the second mode, which is a private mode. Therefore, the second mode may display a video at a smaller viewing angle than in the first mode.

The first light-blocking layer W310, in which the first openings W310-OP are defined, may overlap the first region A1, or the second light-blocking layer 410 may not overlap the first region A1. Therefore, in the first mode, light emitted at a first angle AG1 from the first light-emitting elements WPER and WPEG may be viewed from the user or someone outside who views at high-angle.

The first light-blocking layer N310, in which the first openings N310-OP are defined, may overlap the second region A2, and an area of the first openings N310-OP that overlap the second region A2 may be relatively smaller than an area of the first openings W310-OP that overlap the first region A1. In some aspects, the second light-blocking layer 410 may be formed to overlap the second region A2. Therefore, in the first mode and the second mode, light emitted from the second light-emitting elements NPER and NPEG at the first angle AG1 may not be viewed by someone outside.

According to an embodiment of the inventive concept, a structure that include the first light-blocking layer N310, in which the first openings N310-OP having a relatively small area are defined, and include the second light-blocking layer 410, may display a screen at a small viewing angle, compared to a structure that includes the first light-blocking layer W310 in which the first openings N310-OP having a relatively larger area and does not include the second light-blocking layer 410. Therefore, a display module according to an embodiment of the inventive concept and an electronic device including the display module may display a screen at a smaller viewing angle in a second mode, which is a private mode, and thus may achieve an effect of strengthened privacy protection.

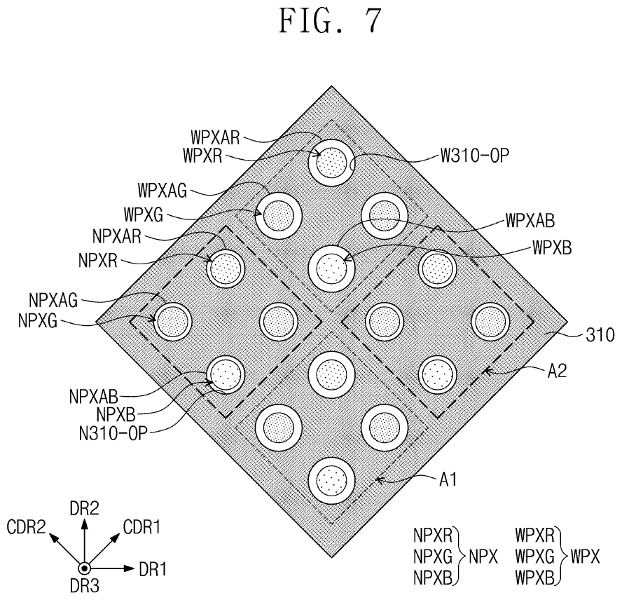

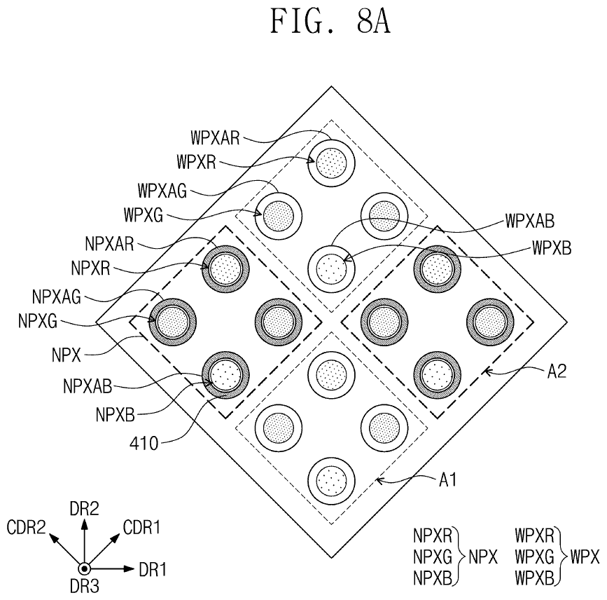

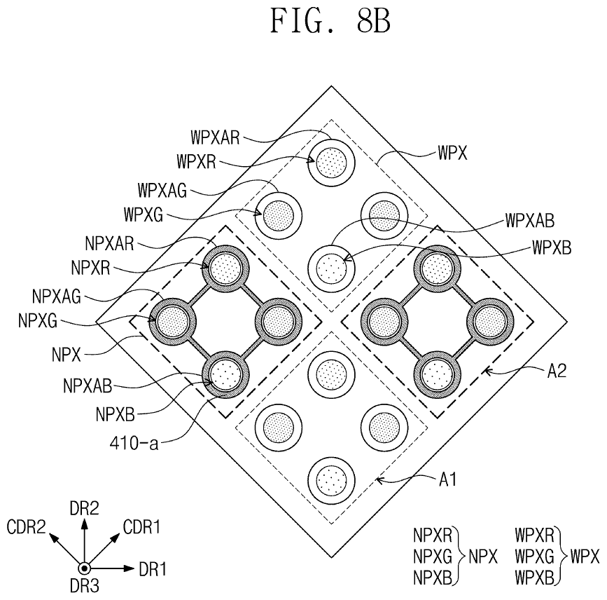

FIG. 7 is a plan view illustrating a portion of a first light-blocking layer according to an embodiment of the inventive concept. FIG. 7 illustrates a plan view of a first light-blocking layer 310 corresponding to the first pixel group WPX and the second pixel group NPX, each illustrated in FIG. 5. The first light-blocking layer 310 in FIG. 7 is illustrated to both the first light-blocking layer W310 in FIG. 6A and the first light-blocking layer N310 in FIG. 6B. FIG. 8A is a plan view illustrating a portion of the second light-blocking layer 410 according to an embodiment of the inventive concept. FIG. 8B is a plan view illustrating a portion of the first light-blocking layer 410-A according to another embodiment of the inventive concept. FIG. 8A and FIG. 8B illustrate plan views of the second light-blocking layer 410 and the second light-blocking layer 410-a corresponding to the first pixel group and the second pixel group NPX, respectively. In some embodiments, identical/similar reference numerals will be used for configurations that are identical/similar to those described in FIG. 5, and duplicated descriptions will be omitted.

Referring to FIG. 7 and FIG. 8A, light provided in the first pixel group WPX that overlaps the first region A1 may pass through the first openings W310-OP and be viewed to the user. The user who uses the display module DD (see FIG. 6A) according to an embodiment of the inventive concept may view, in the first mode, both the light that is provided in the first pixel group WPX and passes through the first openings W310-OP and the light that is provided in the second pixel group NPX and passes through the second openings 410-OP. In some embodiments, the user may view, in the second mode, light that is provided in the second pixel group NPX and passes through the first openings N310-OP and the second openings 410-OP.

The first openings W310-OP defined in a light-blocking layer W310 that overlaps the first region A1 may have a larger area than the first openings N310-OP defined in a light-blocking layer N310 that overlaps the second region A2. Therefore, the user may have a smaller viewing angle in a second mode than in a first mode.

The second light-blocking layer 410 may not overlap the first region A1 and, for example, may overlap only the second region A2. Therefore, among light emitted from the second light-emitting elements NPER and NPEG, high-angle light which is not blocked by the first light-blocking layer N310 may be blocked by the second light-blocking layer 410.

Referring to FIG. 8A and FIG. 8B, the second light-blocking layer 410 and the second light-blocking layer 410-a may have a shape surrounding the second pixel regions NPXAR, NPXAG, and NPXAB. The second light-blocking layer 410 and the second light-blocking layer 410-a may have ring shapes respectively surrounding the second pixel regions NPXAR, NPXAG, and NPXAB. However, this is an example, and the second light-blocking layer 410 and the second light-blocking layer 410-a may have another shape, for example, a polygonal shape in addition to the ring shape, according to the shape of the second pixel regions NPXAR, NPXAG, and NPXAB. The second light-blocking layer 410 surrounding each of the second pixel regions NPXAR, NPXAG, and NPXAB may have island shapes separated from each other. Alternatively, the second light-blocking layer 410-a surrounding each of the second pixel regions NPXAR, NPXAG, and NPXAB may have shapes that are connected to each other. If the second light-blocking layer 410-a is formed of shapes being connected to each other, environment and processes-induced peeling may be prevented. However, embodiments of the present disclosure are not limited thereto.

FIG. 9A and FIG. 9B are each a cross-sectional view schematically illustrating the light-emitting element according to an embodiment. FIG. 9A, schematically illustrates a first light-emitting element WPE overlapping the first region A1, and FIG. 9B, schematically illustrates a second light-emitting element NPE overlapping the second region A2. The second light-emitting element NPE in FIG. 9B corresponds to the first light-emitting element WPE in FIG. 9A, and the first light-emitting element WPE and the second light-emitting element NPE may emit light with the same color. For example, the first light-emitting element WPE in FIG. 9A may be the above-described (1-1)-st light-emitting element WPER in FIG. 6A, and the second light-emitting element NPE in FIG. 9B may be the above-described (2-1)-st light-emitting element NPER in FIG. 6B. Alternatively, the first light-emitting element WPE in FIG. 9A may be the above-described (1-2)-nd light-emitting element WPEG in FIG. 6A, and the second light-emitting element NPE in FIG. 9B may be the above-described (2-2)-nd light-emitting element NPEG in FIG. 6B, but is not limited thereto. Identical/similar reference numerals will be used for configurations that are identical/similar to those described in FIG. 4 to FIG. 8B, and duplicated descriptions will be omitted.

Referring to FIG. 9A, the first light-emitting element WPE may include a first electrode WAE, a first hole transport region WHTR, a first emission layer WEL, an electron transport region ETR, and a second electrode CE, which are sequentially stacked.

The first hole transport region WHTR is provided on the first electrode WAE in the first region A1. The first hole transport region WHTR may include a hole injection layer HIL and a first hole transport layer WHTL. The first hole transport region WHTR may further include a buffer layer, or at least one among an emission auxiliary layer and an electron blocking layer.

The hole transport region WHTR may have a single layer formed using a single material, a single layer formed using a plurality of different materials, or a multilayered structure including a plurality of layers formed using a plurality of different materials. For example, the first hole transport region WHTR may also have a single layer of a hole injection layer HIL or a first hole transport layer WHTL, and the first hole transport region WHTR may also have a single-layered structure formed using hole injection materials and hole transport materials. In some aspects, the first hole transport region WHTR may have a single-layered structure formed using a plurality of different materials, or may have a stacked structure from the first electrode WAE of hole injection layer HIL/hole transport layer HTL, hole injection layer HIL/hole transport layer HTL/buffer layer (not illustrated), hole injection layer HIL/buffer layer (not illustrated), or hole injection layer HIL/hole transport layer HTL/electron-blocking layer (not illustrated), but embodiments of the present disclosure are not limited thereto.

The hole transport region WHTR may have a thickness ranging from about 100 Å to about 10000 Å, for example, from about 100 Å to about 5000 Å. The hole injection layer HIL may have a thickness ranging, for example, from about 30 Å to about 1000 Å. The hole transport layer WHTL may have a thickness (T_{W1}) ranging, for example, from about 30 Å to about 1000 Å. In an example in which the thicknesses of the first hole transport region WHTR, the hole injection layer HIL, and the first hole transport layer WHTL each falls within the above-described range, hole transport characteristics in a satisfying level may be obtained without a substantial increase in driving voltage.

The first hole transport region WHTR may be formed using various methods such as, for example, vacuum deposition, spin coating, a cast method, a Langmuir-Blodgett method, inkjet printing, laser printing, and laser induced thermal imaging (LITI).

The first hole transport region WHTR may contain a compound represented by Formula H-1 below.

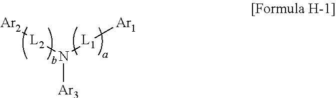

In Formula H-1, L₁ and L₂ may be each independently a direct linkage, a substituted or unsubstituted arylene group having 6 to 30 ring-forming carbons, or a substituted or unsubstituted heteroarylene group having 2 to 30 ring-forming carbons. a and b may be each independently an integer of 0 to 10. In some embodiments, if a or b is an integer of 2 or greater, a plurality of L₁ and L₂ may be each independently a substituted or unsubstituted arylene group having 6 to 30 ring-forming carbons, or a substituted or unsubstituted heteroarylene group having 2 to 30 ring-forming carbons.

In Formula H-1, Ar₁ and Ar₂ may be each independently a substituted or unsubstituted aryl group having 6 to 30 ring-forming carbons, or a substituted or unsubstituted heteroaryl group having 2 to 30 ring-forming carbons. In some aspects, in Formula H-1, Ar₃ may be each independently a substituted or unsubstituted aryl group having 6 to 30 ring-forming carbons, or a substituted or unsubstituted heteroaryl group having 2 to 30 ring-forming carbons.

A compound represented by Formula H-1 above may be a monoamine compound. Alternatively, the compound represented by Formula H-1 above may be a diamine compound in which at least one among Ar₁ to Ar₃ include an amine group as a substituent. In some aspects, the compound represented by Formula H-1 above may be a carbazole-based compound including a carbazole group unsubstituted or substituted for at least one among Ar₁ and Ar₂, or may be a fluorene-based compound including a fluorene group unsubstituted or substituted for at least one among Ar₁ and Ar₂.

In some embodiments, as used herein, “substituted or unsubstituted” may mean being substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocycle. In some aspects, each substituent suggested above may be substituted or unsubstituted. For example, a biphenyl group may also be interpreted as an aryl group, and a phenyl group substituted with a phenyl group.

In the description, the term “forming a ring via the combination with an adjacent group” may mean forming a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocycles or polycycles. In some aspects, the ring formed via the combination with an adjacent group may be combined with another ring to form a spiro structure.

In the description, the term “adjacent group” may mean a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. In some aspects, in 4,5-dimethylphenanthrene, two methyl groups may be interpreted as “adjacent groups” to each other.

In the description, a halogen atom may be a fluorine atom, a chlorine atom, a bromine atom or an iodine atom.

In the description, an alkyl group may be linear, or branched. The carbon number of an alkyl group may be 1 to 50, 1 to 30, 1 to 20, or 1 to 10, or 1 to 6. Examples of the alkyl group may include a methyl group, an ethyl group, an n-propyl group, an isopropyl group, an n-butyl group, a s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, a 3-methylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, a n-heptadecyl group, an n-octadecyl group, an n-nonadecyl group, an n-icosyl group, a 2-ethylicosyl group, a 2-butylicosyl group, a 2-hexylicosyl group, a 2-octylicosyl group, an n-Henicosyl group, an n-Docosyl group, an n-Tricosyl group, an n-Tetracosyl group, an n-pentacosyl group, an n-hexacosyl group, an n-heptacosyl group, an n-oacosyl group, an n-nonacosyl group, an n-triacontyl group, etc., but are not limited thereto.

In the description, a cycloalkyl group may refer to a cyclic alkyl group. The carbon number of the cycloalkyl group may be 3 to 60, 3 to 30, 3 to 20, or 3 to 10. Examples of cycloalkyl group include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but are not limited thereto.

In the description, an alkenyl group means a hydrocarbon group including one or more carbon double bonds in the middle or at the end of an alkyl group having carbons of 2 or more. The alkenyl group may be a linear chain or a branched chain. The carbon number is not particularly limited, but is 2 to 30, 2 to 20, or 2 to 10. Examples of alkenyl group include a vinyl group, a 1-butenyl group, a 1-pentenyl group, a 1,3,-butadienyl aryl group, a sternly group, a styrenyl group, a styryl vinyl group, but are not limited thereto.

In the description, an alkynyl group means a hydrocarbon group including one or more carbon triple bonds in the middle or at the terminal of an alkyl group having a carbon number of 2 or more. The alkynyl group may be a linear chain or a branched chain. The carbon number is not specifically limited, but may be 2 to 30, 2 to 20, or 2 to 10. Particular examples of the alkynyl group include an ethynyl group, a propynyl group, etc., but are not limited thereto.

In the description, a hydrocarbon ring group means any functional group or a substituent, which is derived from an aliphatic hydrocarbon ring. The hydrocarbon ring group may be a saturated hydrocarbon ring group having ring-forming carbons of 5 to 20.

In the description, an aryl group means an optional functional group or substituent derived from an aromatic hydrocarbon ring. The aryl group may be a monocyclic aryl group or a polycyclic aryl group. The carbon number for forming rings in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but are not limited thereto.

In the description, a fluorenyl group may be substituted, and two substituents may be combined with each other to form a spiro structure. Examples of a substituted fluorenyl group are as follows, but embodiments of the present disclosure are not limited thereto.

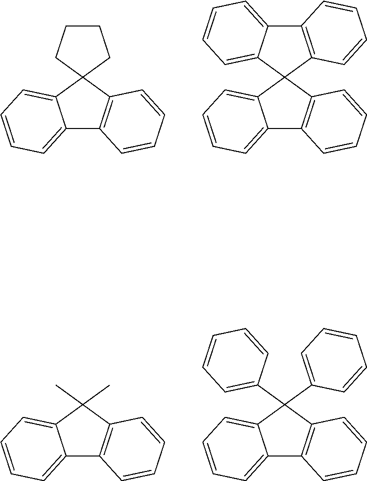

In the description, a heterocyclic group means a functional group or substituent derived from a ring including one or more among B, O, N, P, Si, S and Se as heteroatoms. The heterocyclic group includes an aliphatic heterocyclic group and an aromatic heterocyclic group. The aromatic heterocyclic group may be a heteroaryl group. The aliphatic heterocyclic group and the aromatic heterocyclic group may be a monocycle or a polycycle.

The heterocyclic group may include one or more among B, O, N, P, Si, and S as heteroatoms. If the heterocyclic group includes two or more heteroatoms, two or more heteroatoms may be the same or different. The heterocyclic group may be a monocyclic heterocyclic group or a polycyclic heterocyclic group, and has the concept including a heteroaryl group. The carbon number for forming rings of the heterocyclic group may be 2 to 30, 2 to 20, and 2 to 10.

In the description, an aliphatic heterocyclic group may include one or more among B, O, N, P, Si, S and Se as heteroatoms. The number of ring-forming carbon atoms of the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments of the present disclosure are not limited thereto.

In the description, a heteroaryl group may contain one or more among B, O, N, P, Si, and S as heteroatoms. If a heteroaryl group contains two or more heteroatoms, two heteroatoms may be the same as, or different from each other. The heteroaryl group may be a monocyclic heterocycle group, or a polycyclic heterocycle group. The carbon number of the heteroaryl group may be 2 to 30, 2 to 20, or 2 to 10. Examples of heteroaryl group include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but is not limited thereto.

In the description, the descriptions of the aryl group may be similarly applied to an arylene group except that the arylene group is divalent. The descriptions of the heteroaryl group may be similarly applied to a heteroarylene group except that the heteroarylene group is divalent.

In the description, a silyl group includes an alkyl silyl group, and an aryl silyl group. Examples of the silyl group include a trimethyl silyl group, a triethyl silyl group, a t-butyldimethyl silyl group, a vinyldimethyl silyl group, a propyldimethyl silyl group, a triphenyl silyl group, a diphenyl silyl group, a phenylsilyl group, etc., but are not limited thereto.

In the description, the carbon number of a carbonyl group is not particularly limited, but the carbon number may be 1 to 40, 1 to 30, or 1 to 20. For example, the carbonyl group may have a following structure, but is not limited thereto.

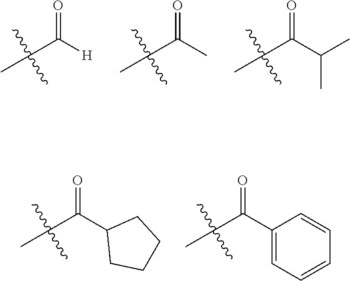

In the description, the carbon number of a sulfinyl group or sulfonyl group is not particularly limited, but may be 1 to 30. The sulfinyl group may include an alkyl sulfinyl group, and an aryl sulfinyl group. The sulfonyl group may include an alkyl sulfonyl group, and an aryl sulfonyl group.

In the description, a thio group may include an alkyl thio group and an aryl thio group. The thio group may mean the above-defined alkyl group or aryl group combined with a sulfur atom. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but are not limited thereto.

In the description, an oxy group may mean the above-defined alkyl group or aryl group which is combined with an oxygen atom. The oxy group may include an alkoxy group and an aryl oxy group. The alkoxy group may be a linear, branched or cyclic chain. The carbon number of the alkoxy group is not particularly limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc. However, embodiments of the present disclosure are not limited thereto.

In the description, a boron group may mean the above-defined alkyl group or aryl group which is combined with a boron atom. The boron group includes an alkyl boron group and an aryl boron group. Examples of the boron group include a trimethylboron group, a triethylboron group, a t-butyldimethylboron group, a triphenylboron group, a diphenylboron group, a phenylboron group, etc., but are not limited thereto.

As used herein, the carbon number of amine group is not particularly limited, but the amine group may have carbons of 1 to 30. The amine group may include an alkylamine group, and an arylamine group. Examples of amine group may include a methylamine group, a dimethylamine group, a phenylamine group, a diphenylamine group, a naphthylamine group, a 9-methyl-anthracenyl amine group, etc., but are not limited thereto.

In the description, the alkyl group in an alkylthio group, an alkylsulfoxide group, an alkylaryl group, an alkylamino group, an alkylboron group, an alkylsilyl group, and an alkylamine group are the same as the examples of alkyl group described previously.

In the description, the aryl group in an aryloxy group, an arylthio group, an arylsulfoxide group, an arylamino group, an arylboron group, an arylsilyl group, and an arylamine group are the same as the examples of aryl group described previously.

In the description, a direct linkage may mean a single bond.

In some embodiments, as used herein,

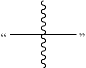

and “-*” may mean a position connected.

The compound represented by Formula H-1 may be represented by any one among compounds in Compound Group H below. However, the compounds suggested in Compound Group H below are for illustrative purposes, but the compound represented by Formula H-1 is not limited to the compounds present in Compound Group H below.

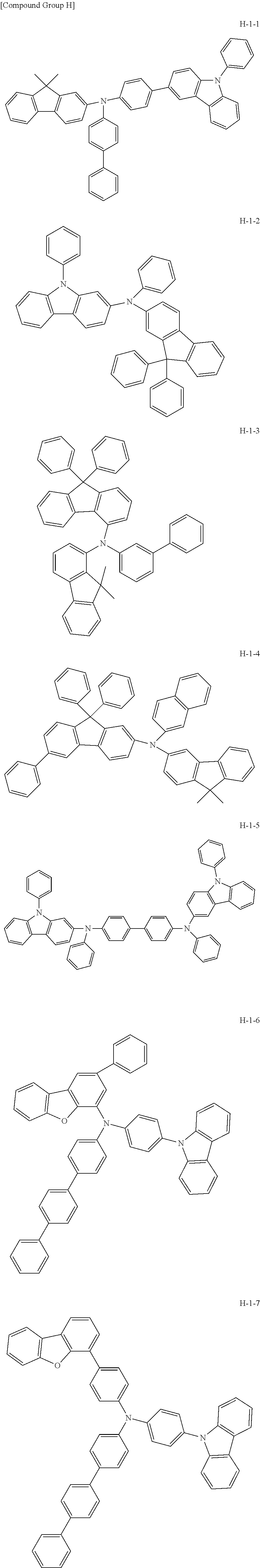

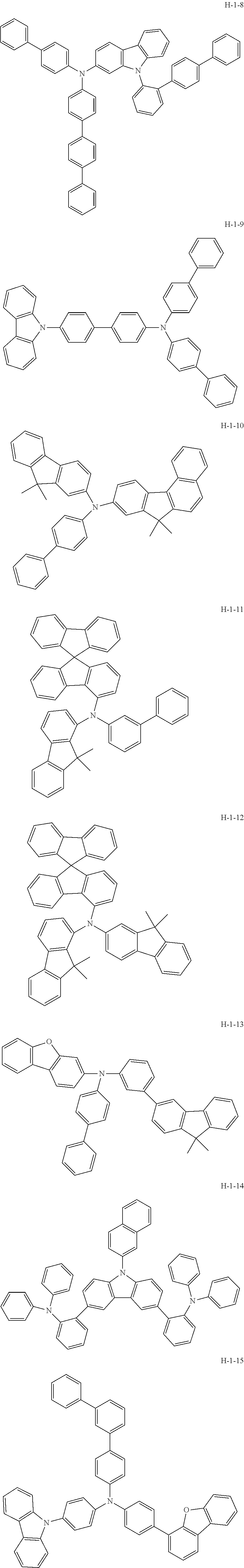

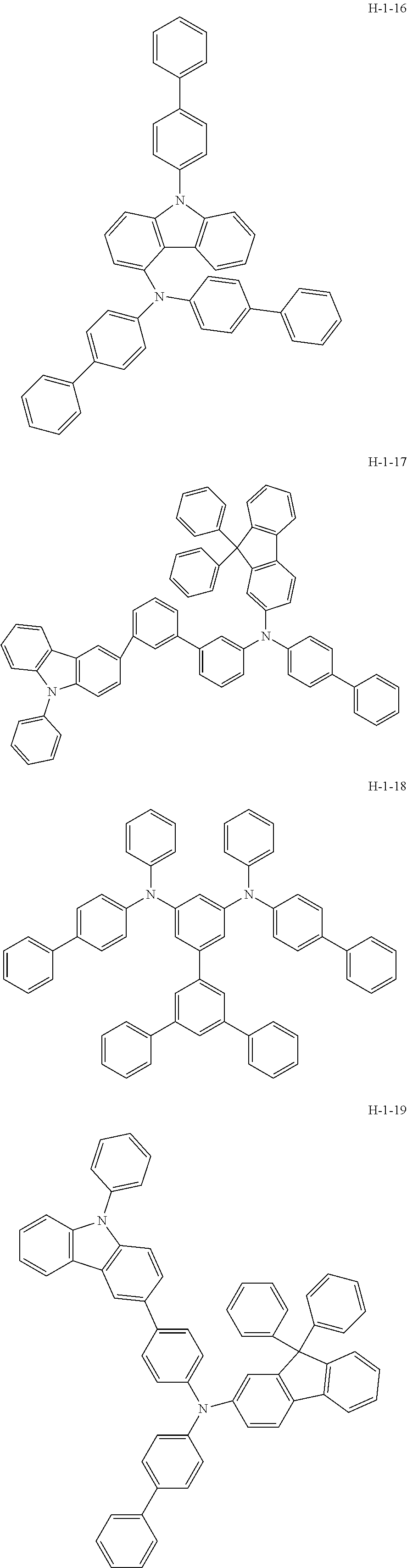 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The first hole transport region WHTR may include a phthalocyanine compound such as, for example, copper phthalocyanine, N1,N1-([1,1′-biphenyl]-4,4′-diyl)bis(N1-phenyl-N4,N4-di-m-tolylbenzene-1,4-diamine) (DNTPD), 4,4′,4″-[tris(3-methylphenyl)phenylamino] triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), poly ether ketone containing triphenylamine (TPAPEK), 4-isopropyl-4′-methyldiphenyliodonium[tetrakis(pentafluorophenyl) borate], dipyrazino[2,3-f: 2′,3′-h]quinoxaline-2,3,6,7,10,11-hexacarbonitrile (HATCN), etc.

The first hole transport region WHTR may also include a carbazole-based derivative such as, for example, N-phenylcarbazole, and polyvinylcarbazole, a fluorene-based derivative, a triphenylamine-based derivative such as, for example, N,N′-bis(3-methylphenyl)-N,N′-diphenyl-[1,1′-biphenyl]-4,4′-diamine (TPD), and 4,4′,4″-tris(N-carbazolyl)triphenylamine (TCTA), N,N′-di(naphthalene-1-yl)-N,N′-diphenyl-benzidine (NPB), 4,4′-cyclohexylidenebis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some aspects, the first hole transport region WHTR may include 9-(4-tert-butylphenyl)-3,6-bis(triphenylsilyl)-9H-carbazole (CzSi), 9-phenyl-9H-3,9′-bicarbazole (CCP), or 1,3-bis(1,8-dimethyl-9H-carbazol-9-yl)benzene (mDCP).

The first hole transport region WHTR may further include a charge generation material for improving conductivity in addition to the above-described materials. For example, the hole injection layer HIL may further include a charge generation material for improving conductivity. The charge generation material may be uniformly or evenly dispersed within the hole injection layer HIL. The charge generation material may be, for example, a p-dopant. The p-dopant may contain at least one among a metal halide compound, a quinone derivative, a metal oxide, and a cyano group-containing compound, but is not limited thereto. For example, the p-dopant may include, but is not particularly limited thereto. For example, the p-dopant may include a metal halide metal such as, for example, CuI and RbI., a quinone derivative such as, for example, tetracyanoquinodimethane (TCNQ) and 2,3,5,6-tetrafluoro-7,7′8,8-tetracyanoquinodimethane (F4-TCNQ), a metal oxide such as, for example, tungsten oxide and molybdenum oxide, and a cyano-containing compound such as, for example, dipyrazino[2,3-f: 2′,3′-h]quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), but embodiments of the present disclosure are not limited thereto.

The first emission layer WEL is provided on the first hole transport region WHTR in the first region A1. The first emission layer WEL may have a single layer formed using a single material, a single layer formed using a plurality of different materials, or a multi-layered structure having a plurality of layers formed using a plurality of different materials.

The first emission layer WEL may have a thickness of T_{W2} ranging from about 100 Å to about 1000 Å. For example, the first emission layer WEL may have a thickness ranging from about 100 Å to about 300 Å.

The first emission layer WEL may include an anthracene derivative, a pyrene derivative, a fluoranthene derivative, a chrysene derivative, a dihydrobenzanthracene derivative, or a triphenylene derivative. Specifically, the first emission layer WEL may include an anthracene derivative, or a pyrene derivative.

The first emission layer WEL may be formed using various methods such as, for example, vacuum deposition, spin coating, a cast method, a Langmuir-Blodgett method, inkjet printing, laser printing, and laser induced thermal imaging (LITI).

The first emission layer WEL may include a host and a dopant. The first emission layer WEL may include a compound represented by Formula E-1 below. For example, the first emission layer WEL may include the compound represented by Formula E-1 below. The compound represented by Formula E-1 below may be used as a fluorescent host material.

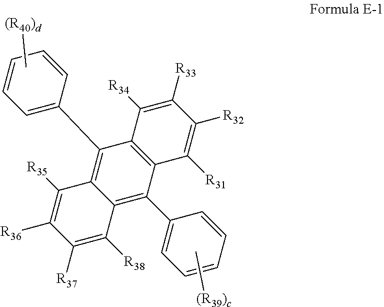

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbons, a substituted or unsubstituted alkenyl group having 2 to 10 carbons, a substituted or unsubstituted aryl group having 6 to 30 ring-forming carbons, or a substituted or unsubstituted heteroaryl group having 2 to 30 ring-forming carbons, or may be combined with an adjacent group to form a ring. In some embodiments, R₃₁ to R₄₀ may be combined with an adjacent group to form a saturated hydrocarbon ring, an unsaturated hydrocarbon ring, a saturated heterocycle, or an unsaturated heterocycle.

In Formula E-1, c and d may be each independently an integer of 0 to 5.

Formula E-1 may be represented by any one among Formula E1 to Formula E19 below.

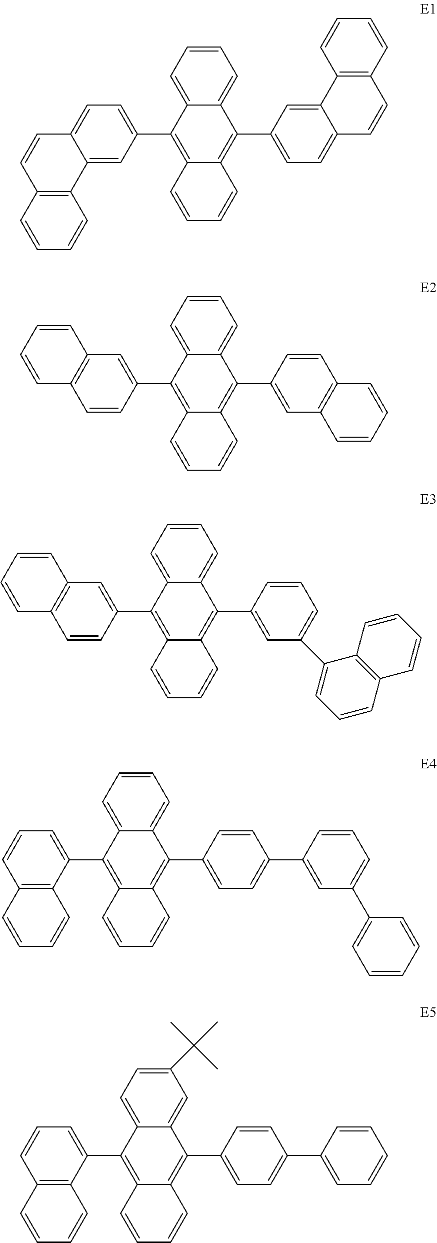

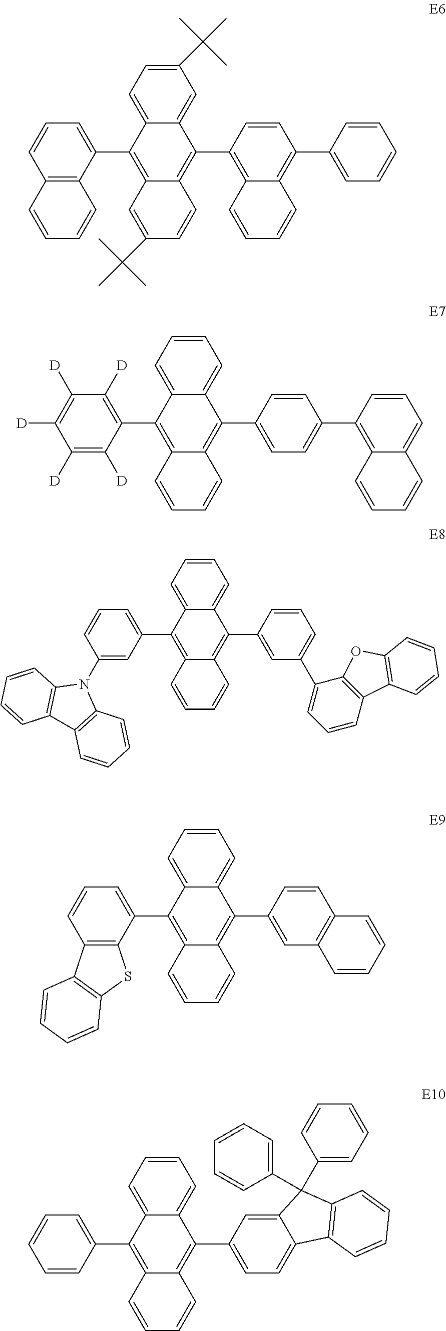

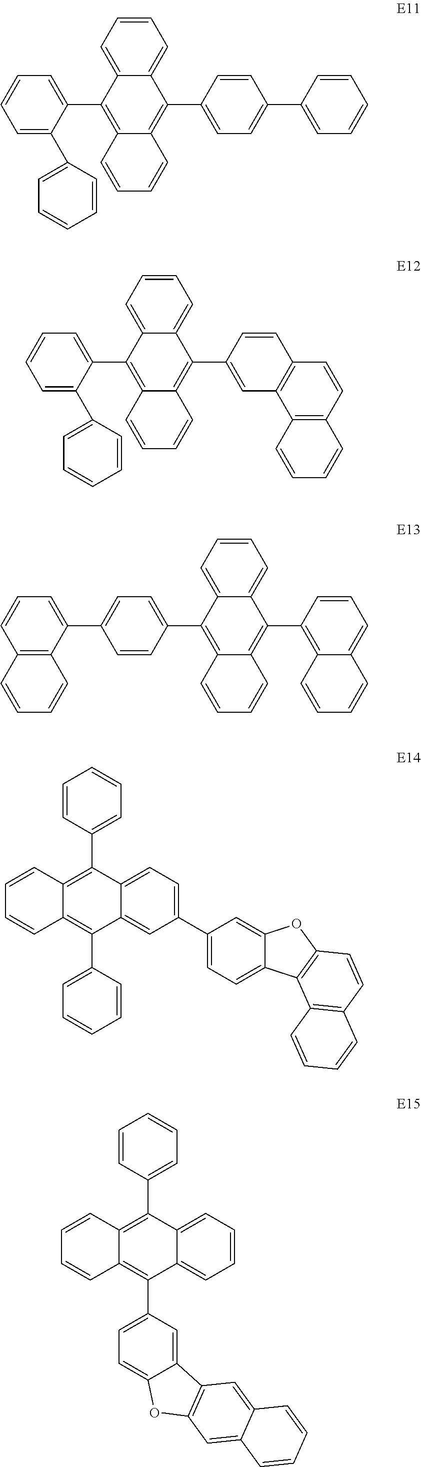

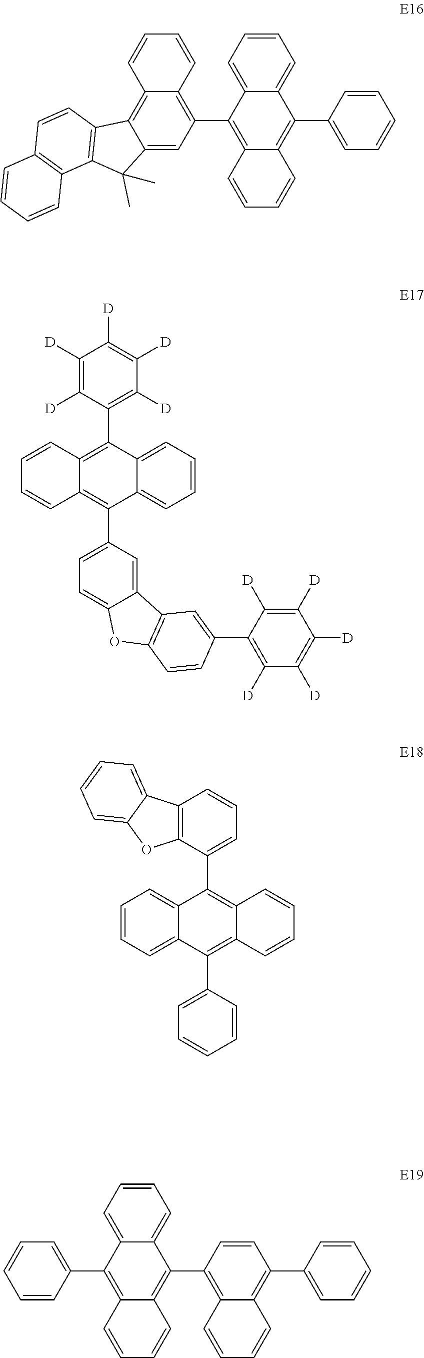

The first emission layer WEL may include a compound represented by Formula E-2a or Formula E-2b below. The compound represented by Formula E-2a or Formula E-2b below may be used as a phosphorescent host material.

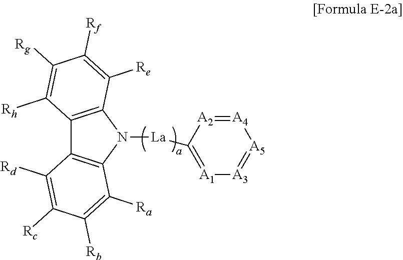

In Formula E-2a, a is an integer of 0 to 10, L is a direct linkage, a substituted or unsubstituted arylene group having 6 to 30 ring-forming carbons, or a substituted or unsubstituted heteroarylene group having 2 to 30 ring-forming carbons. In some embodiments, if a is an integer of 2 or greater, the plurality of La may be each independently a substituted or unsubstituted arylene group having 6 to 30 ring-forming carbons, or a substituted or unsubstituted heteroarylene group having 2 to 30 ring-forming carbons.

In some aspects, in Formula E-2a, A₁ to A₅ may be each independently N, or CRᵢ. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or combine with an adjacent group to form a ring. Rₐ to Rᵢ may be combined with an adjacent group to form a heterocycle containing a hydrocarbon ring, N, O, or S as a ring-forming atom.

In Formula E-2a, two or three selected from among A₁ to A₅ may be N, and the other may be CRᵢ.

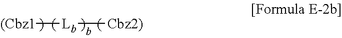

In Formula E-2b, Cbz1 and Cbz2 may be each independently an unsubstituted carbazole group, or a substituted carbazole group with an aryl group having 6 to 30 ring-forming carbons. L_{b} may be a direct linkage, a substituted or unsubstituted arylene group having 6 to 30 ring-forming carbons, or a substituted or unsubstituted heteroarylene group having 2 to 30 ring-forming carbons. b is an integer of 0 to 10, and if b is an integer of 2 or greater, the plurality of L_{b} may be each independently a substituted or unsubstituted arylene group having 6 to 30 ring-forming carbons, or a substituted or unsubstituted heteroarylene group having 2 to 30 ring-forming carbons.

The compound represented by Formula E-2a or Formula E-b may be represented by any one among compounds in Compound Group E-2 below. However, the compounds present in Compound Group E-2 below are for illustrative purposes, and the compound represented by Formula E-2a or Formula E-2b is not limited to the compounds present in Compound Group E-2 below.

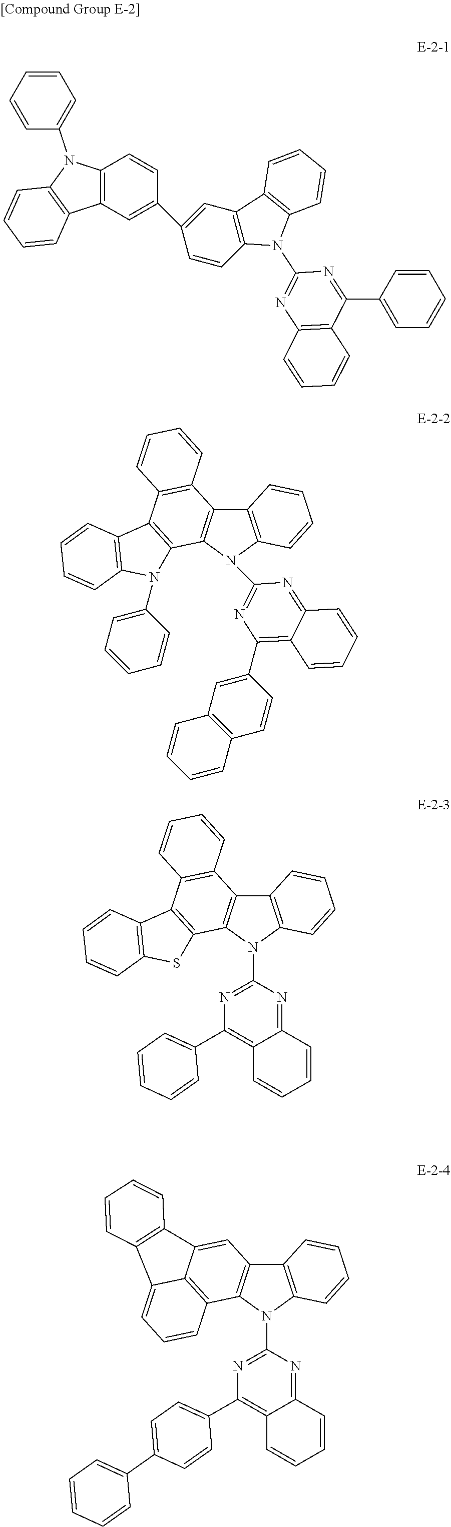

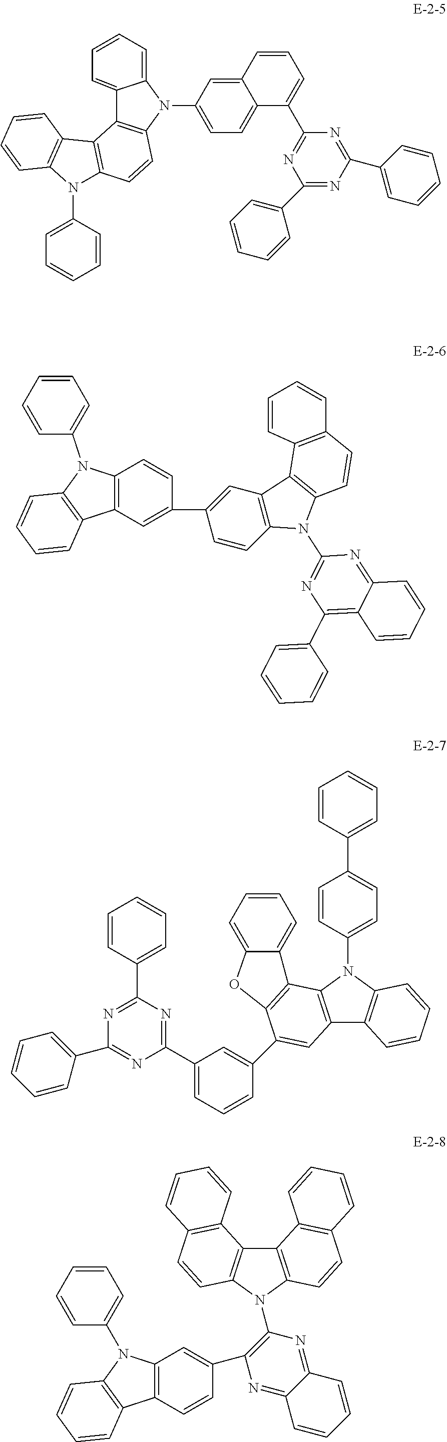 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

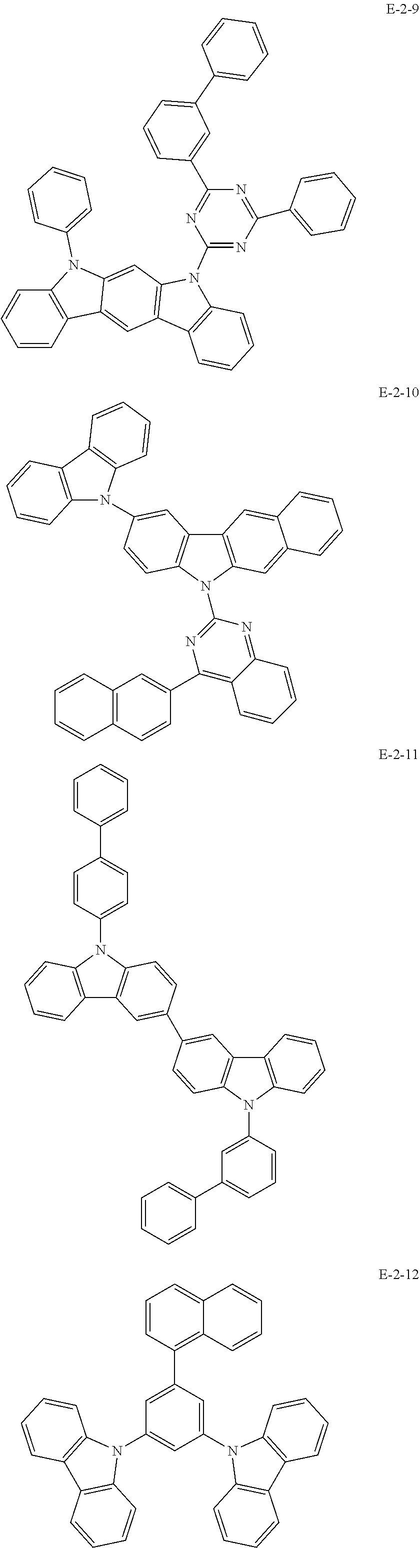

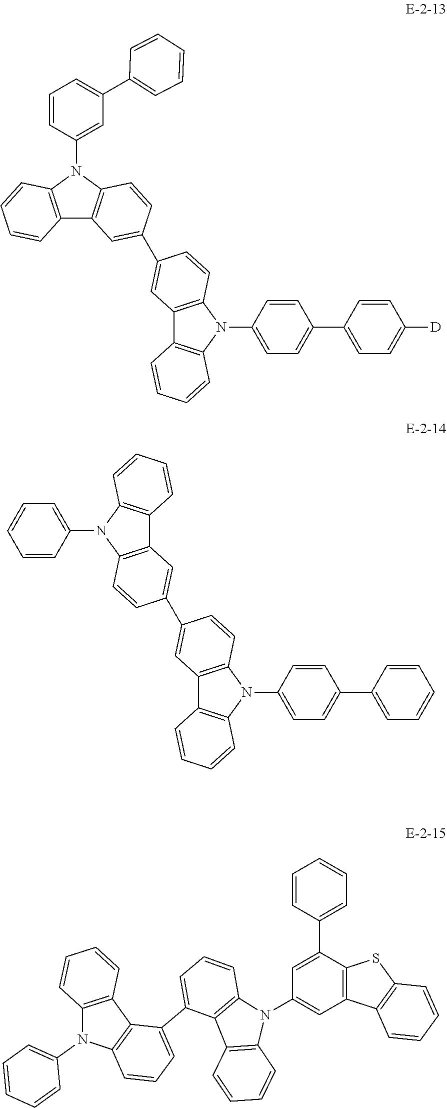 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

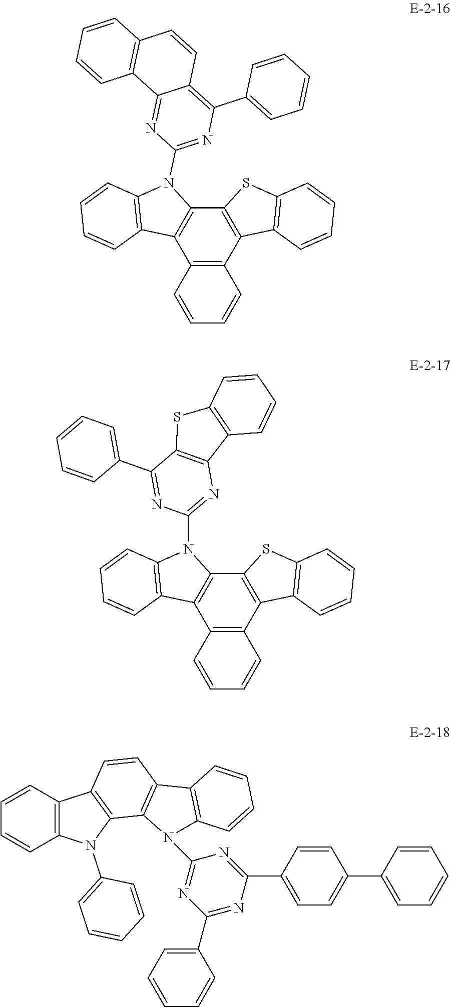 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

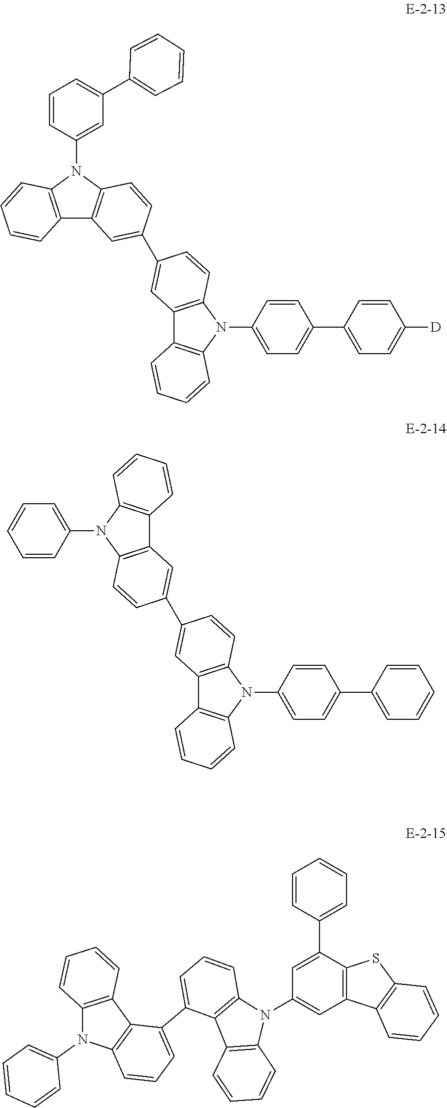 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

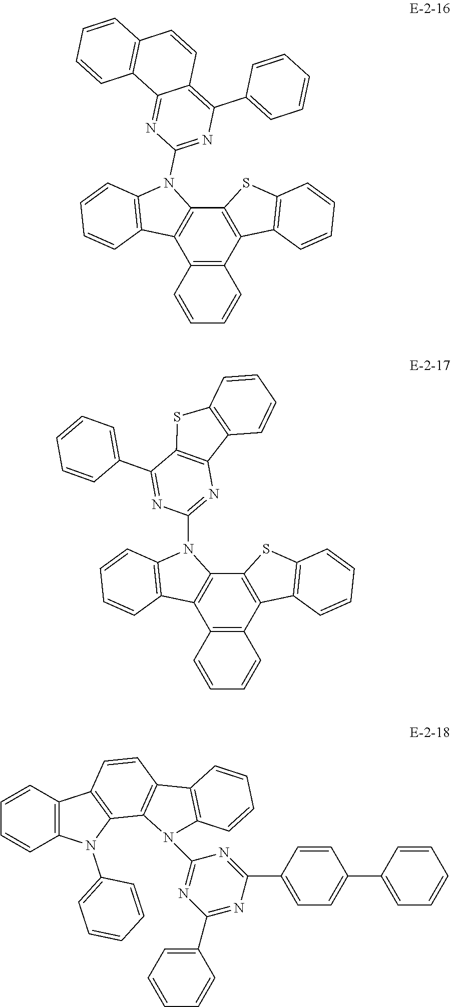 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

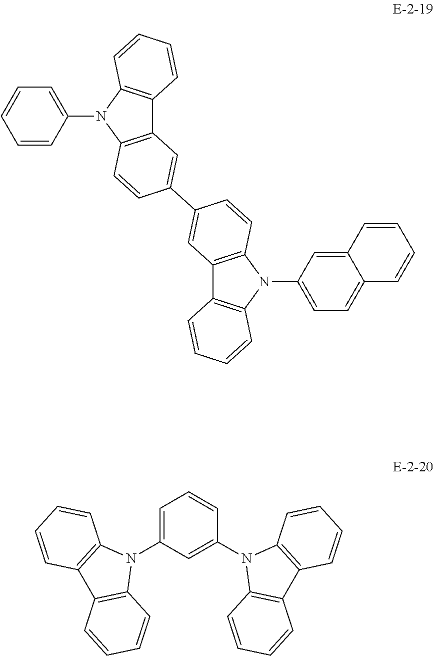 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1]

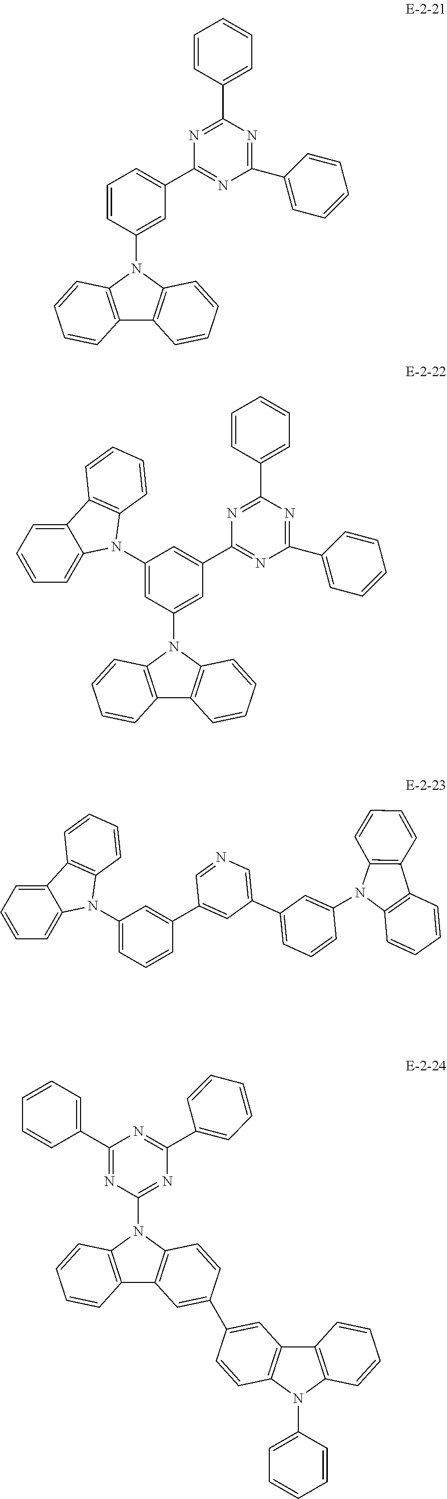 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The first emission layer WEL may further include general materials known in the art as a host material. For example, each of the emission layers EL1 and EL2 may include at least one among as a host material bis(4-(9H-carbazol-9-yl)phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8 Bis(diphenylphosphoryl)dibenzo[b,d]furan (PPF), 4,4′,4″-Tris(carbazol-9-yl)-triphenylamine (TCTA), and 1,3,5-tris(1-phenyl-1H-benzo[d]imidazole-2-yl)benzene (TPBi). However, embodiments of the present disclosure are not limited thereto, and for example, tris(8-hydroxyquinolino)aluminum (Alq₃), 9,10-di(naphthalene-2-yl) anthracene (ADN), 2-tert-butyl-9,10-di(naphth-2-yl) anthracene (TBADN), distyrylarylene (DSA), 4,4′-bis(9-carbazolyl)-2,2′-dimethyl-biphenyl (CDBP), 2-methyl-9,10-bis(naphthalen-2-yl) anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), and the like may be used as a host material.

The first emission layer WEL may contain a compound represented by Formula M-a below.

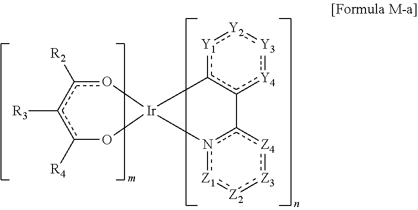

In Formula M-a above, Y₁ to Y₄, and Z₁ to Z₄ may be each independently CR₁ or N, R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or be combined with an adjacent group to form a ring. In Formula M-a, m is 0 or 1, n is 2 or 3, and in Formula M-a, if m is 0, n is 3, and if m is 1, n is 2.

The compound represented by Formula M-a may be represented by any one among Compounds M-a1 to M-a25 below. However, Compounds M-a1 to M-a25 below are for illustrative purposes, the compound represented by Formula M-a is not limited to the compounds present in Compounds M-a1 to M-a25 below.

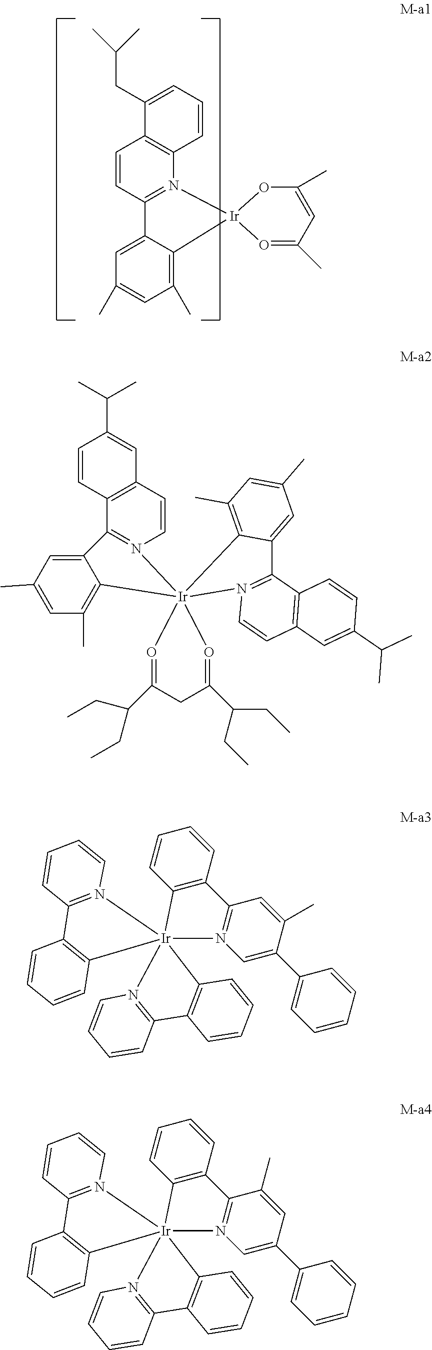

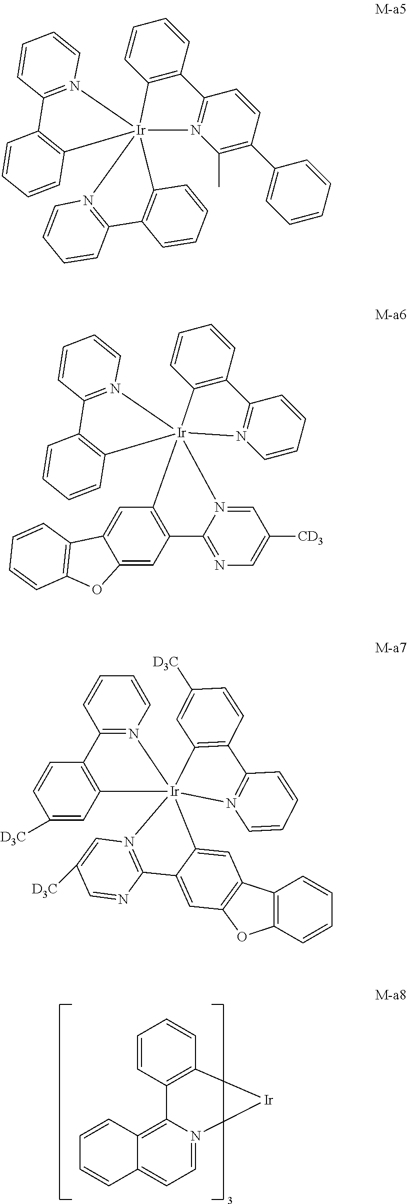

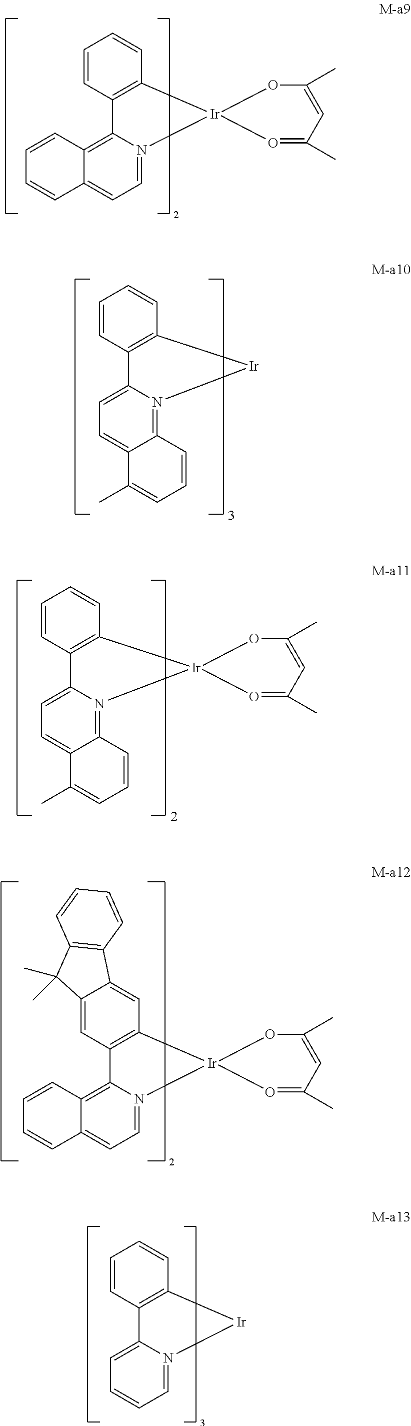

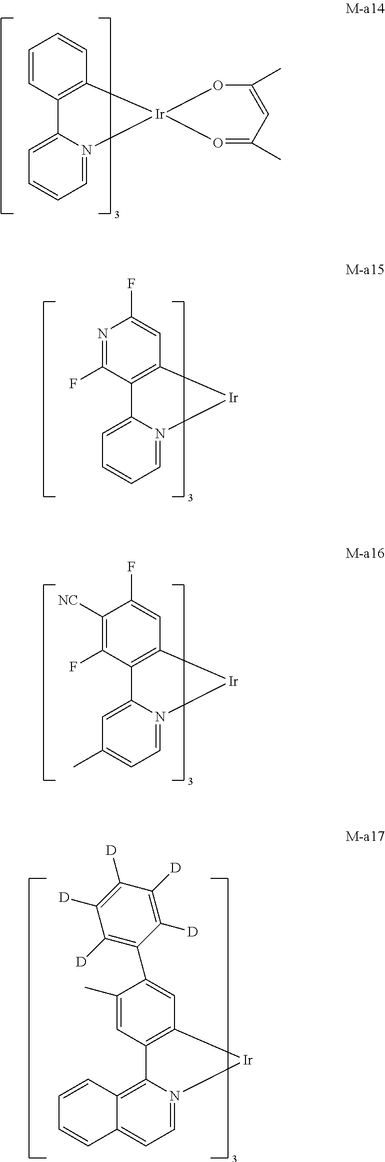

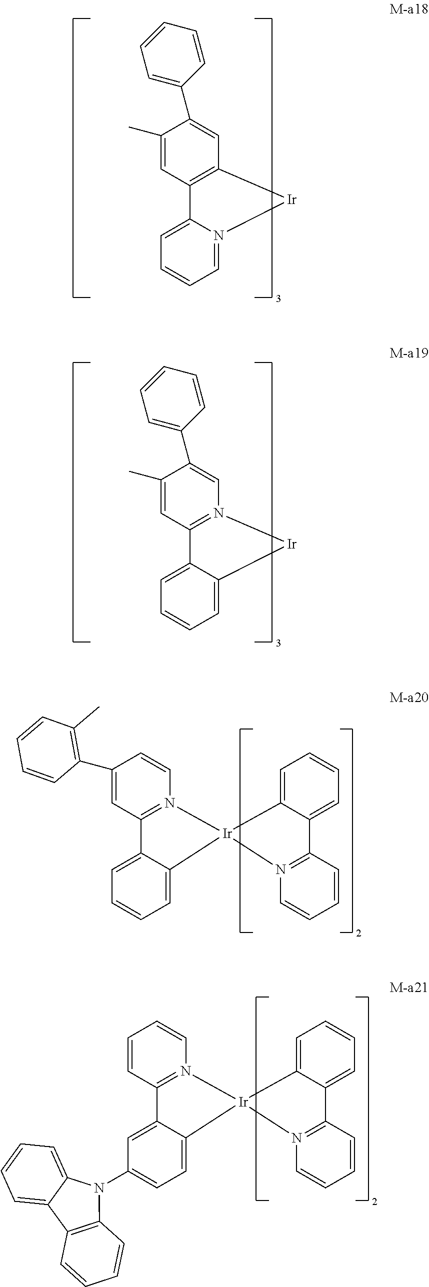

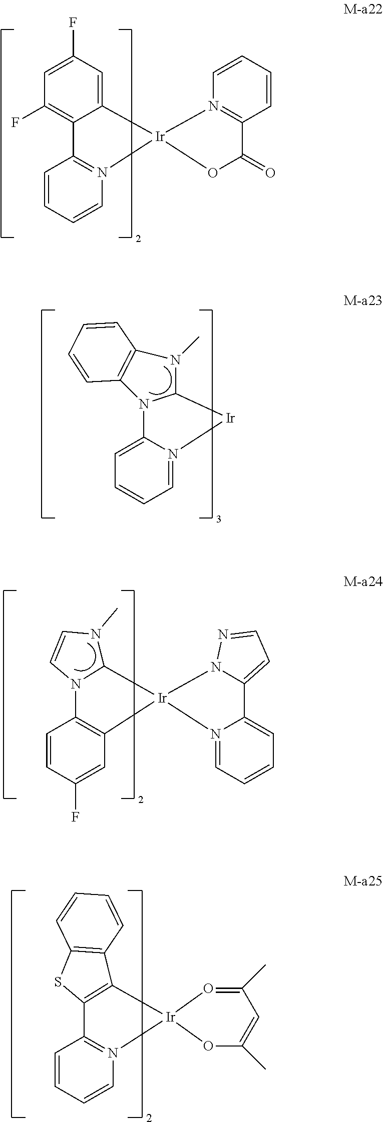

The first emission layer WEL may include a compound represented by any one among Formula F-a to Formula F-c. The compounds represented by Formula F-a to Formula F-c below may be used as a fluorescent dopant material.

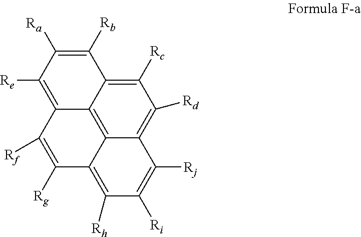

In Formula F-a above, two selected from among Rₐ to Rⱼ may be each independently substituted with

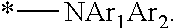

The other that are unsubstituted with

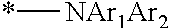

may be each independently a hydrogen atom, a deuterium atom, a halogen atom, a cyano group, a substituted or unsubstituted amine group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons. In

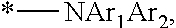

Ar₁ and Ar₂ may be each independently a substituted or unsubstituted aryl group having 6 to 30 ring-forming carbons, or a substituted or unsubstituted heteroaryl group having 2 to 30 ring-forming carbons. For example, at least one among Ar₁ and Ar₂ may be a heteroaryl group including O or S as a ring-forming atom.

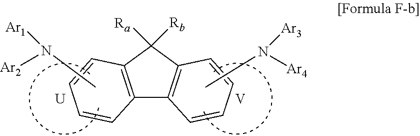

In Formula F-b above, Rₐ and R_{b} may be each independently a hydrogen atom, a deuterium atom, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or combine with an adjacent group to form a ring. Ar₁ to Ar₄ may be each independently a substituted or unsubstituted aryl group having 6 to 30 ring-forming carbons, or a substituted or unsubstituted heteroaryl group having 2 to 30 ring-forming carbons.

In Formula F-b, U and V may be each independently a substituted or unsubstituted hydrocarbon group having ring-forming carbons of 5 to 30, or a substituted or unsubstituted heterocycle having ring-forming carbons of 2 to 30. At least one among Ar₁ to Ar₄ may be a heteroaryl group containing O or S as a ring-forming atom.

In Formula F-b, the number of rings designated with U or V may be each independently 0 or 1. For example, it means that in Formula F-b, if the number of U or V is 1, one ring forms a fused ring at a portion where is designated with U or V, and if the number of U or V is 0, there is no ring designated with U or V. Specifically if the number of U is 0 and the number of V is 1, or if the number of U is 1 and the number of V is 0, a fused ring having a fluorene core in Formula F-b may be a four-membered ring compound. In some aspects, the number of both of U and V is 1, a fused ring having a fluorene core in Formula F-b may be a five-membered ring compound.

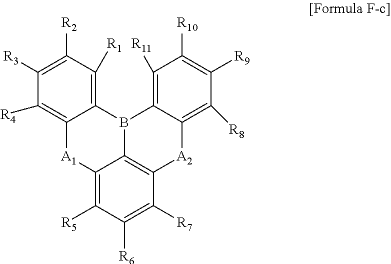

In Formula F-c, A1 and A2 may be each independently O, S, Se, or NRₘ, Rₘ may be a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons. R₁ to R₁₁ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, or combines with an adjacent group to form a ring.

In Formula F-c, A₁ and A₂ may be each independently combined with an adjacent group to form a fused ring. For example, if A₁ and A₂ are each independently NRₘ, A₁ may be combined with R₄ or R₅ to form a ring. In some aspects, A₂ may be combined with R₇ or R₈ to form a ring.

The first emission layer WEL may further include, as a known dopant material, styryl derivatives (for example, 1,4-bis[2-(3-N-ethylcarbazoryl) vinyl]benzene (BCzVB), 4-(di-p-tolylamino)-4′-[(di-p-tolylamino) styryl]stilbene (DPAVB), and N-(4-((E)-2-(6-((E)-4-(diphenylamino) styryl) naphthalen-2-yl) vinyl)phenyl)-N-phenylbenzenamine (N-BDAVBi)), 4,4′-bis[2-(4-(N,N-diphenylamino)phenyl) vinyl]biphenyl (DPAVBi), perylene and derivatives thereof (for example, 2, 5, 8, 11-tetra-t-butylperylene (TBP)), pyrene and derivatives thereof (for example, 1,1-dipyrene, 1,4-dipyrenylbenzene, and 1, 4-bis(N, N-diphenylamino) pyrene), etc.

The first emission layer WEL may further include a known phosphorescent dopant material. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as the phosphorescent dopant. Specifically, iridium (III) bis(4,6-difluorophenylpyridinato-N,C2′) picolinate (FIrpic), bis(2,4-difluorophenylpyridinato)-tetrakis(1-pyrazolyl) borate iridium (III) (Fir6), or platinum octaethyl porphyrin (PtOEP) may be used the phosphorescent dopant. However, embodiments of the present disclosure are not limited thereto.

The first emission layer WEL may include a quantum dot material. A core of the quantum dot may be selected from II-VI group compounds, III-VI group compounds, I-III—VI group compounds, III-V group compounds, III-II-V group compounds, IV-VI group compounds, IV group elements, IV group compounds, and combinations thereof.

The II-VI group compounds may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The III-VI group compound may include a binary compound such as, for example, In₂S₃, and In₂Se₃, a ternary compound such as, for example, InGaS₃, and InGaSe₃, or optional combinations thereof.

The I-III-VI group compound may be selected from a ternary compound selected from the group consisting of AgInS₂, CuInS, CuInS₂, AgGaS₂, CuGaS₂ CuGaO₂, AgGaO₂, AgAlO₂ and mixtures thereof, or a quaternary compound such as, for example, AgInGaS₂, and CuInGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAS, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In some embodiments, the III-V group compound may further include a II group metal. For example, InZnP, etc. may be selected as a III-II-V group compound.

The IV-VI group compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

Each element contained in a multi-element compound such as, for example, the binary compound, the ternary compound and the quaternary compound may be present at uniform concentration or at ununiform concentration in a particle. That is, the Formula refers to types of elements contained in the compound, and an element ratio within the compound may vary. For example, AgInGaS₂ may mean AgInxGa₁₋ₓS₂ (x is a real number of 0 to 1).

In some embodiments, the quantum dot may have a single structure, in which each element contained in the corresponding quantum dot has a uniform concentration, or a double structure of core-shell. For example, materials included in the core and materials included in the shell may be different from each other.

The shell of the quantum dot may serve as a protection layer for maintaining semiconductor properties in order to prevent the core from chemical denaturation and/or serve as a charging layer for imparting electrophoretic characteristics to the quantum dot. The shell may have a single layer, or a multilayer. The interface between the core and the shell may have a concentration gradient in which the concentration of an element present in the shell decreases toward the center.

In some embodiments, the quantum dot may have the above-described core-shell structure including a core including a nanocrystal and a shell surrounding the core. The shell of the quantum dot may serve as a protection layer for maintaining semiconductor properties in order to prevent the core from chemical denaturation and/or serve as a charging layer for imparting the quantum dot with electrophoretic properties. The shell may have a single layer or a multilayer. Examples of the shell of the quantum dot may include a metal or non-metal oxide, a semiconductor compound, or combinations thereof.

For example, the metal or non-metal oxide may include a binary compound such as, for example, SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound such as, for example, MgAl₂O₄, CoFe₂O₄, NiFe₂O₄, and CoMn₂O₄, but embodiments of the present disclosure are not limited thereto.

In some aspects, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AlSb, etc., but embodiments of the present disclosure are not limited thereto. Each element contained multi-element compounds such as, for example, the binary compound, and the ternary compound may be present in a particle at a uniform concentration or non-uniform concentration. That is, the formula may mean types of elements contained in the compound, and an element ratio within the compound may vary.

The quantum dot may have a full width of half maximum (FWHM) of emission wavelength spectrum of about 45 nm or less, preferably, about 40 nm or less, and more preferably, about 30 nm or less. In an example in which the FWHM falls within this range, color purity or color reproducibility may be improved. In some aspects, light emitted via such quantum dot is emitted in all directions, and thus light view angle properties may be improved.

In some aspects, the shape of the quantum dot may be generally used shapes in the art, without specific limitation. More particularly, the shape of sphere, pyramid, multi-arm, or cubic nanoparticle, nanotube, nanowire, nanofiber, nanoplate particle or the like may be used.

An energy band gap may be adjusted by adjusting a size of the quantum dot or an element ratio within the quantum dot compound, and thus light in various wavelengths may be obtained within a quantum dot emission layer. Therefore, by using the above-mentioned quantum dot (using a quantum dot having a different size from each other, or varying element ratio within the quantum dot compound, a light-emitting element which emits light with various wavelengths may be implemented. Specifically, adjustment of the quantum dot size or adjustment of element ratio within the quantum dot compound may be selected for red, green and/or blue light to be emitted. In some aspects, the quantum dots may emit white light by combining light with various colors.

The electron transport region ETR is provided on the first emission layer WEL. The electron transport region ETR may include an electron transport layer ETL and an electron injection layer EIL, but embodiments of the present disclosure are not limited thereto.

The electron transport region ETR may have a single layer formed using a single material, a single layer formed using a plurality of different materials, or a multi-layered structure having multiple layers formed using a plurality of different materials.

The electron transport region ETR may be formed using various methods such as, for example, vacuum deposition, spin coating, a cast method, a Langmuir-Blodgett method, inkjet printing, laser printing, and laser induced thermal imaging (LITI).

For example, the electron transport region ETR may have a single layer of an electron injection layer EIL or electron transport layer ETL, or may have a single layer formed using electron injection materials and electron transport materials. In some aspects, the electron transport region ETR may have a single layer structure formed using a plurality of different materials, or a structure of electron transport layer ETL/electron injection layer EIL, and hole blocking layer (not illustrated)/electron transport layer ETL/electron injection layer EIL, which are sequentially stacked from the first light-emitting layer WEL, but is not limited thereto. The electron transport region ETR may have a thickness of, for example, about 1000 Å to about 1500 Å.

The electron transport region ETR may contain a compound represented by Formula ET-1 below.

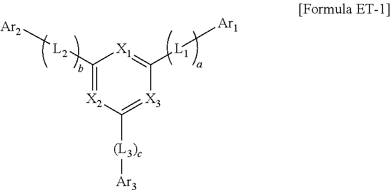

In Formula ET-1, at least one among X₁ to X₃ is N, and the other are CRₐ. Rₐ may be a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons. Ar₁ to Ar₃ may be each independently a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons.

In Formula ET-1, a to c may be each independently an integer of 0 to 10. In ET-1, L₁ to L₃ may be each independently a direct linkage, a substituted or unsubstituted arylene group having 6 to 30 ring-forming carbons, or a substituted or unsubstituted heteroarylene group having 2 to 30 ring-forming carbons. In some embodiments, if a to c is each an integer of 2 or greater, L₁ to L₃ may be each independently a substituted or unsubstituted arylene group having 6 to 30 ring-forming carbons, or a substituted or unsubstituted heteroarylene group having 2 to 30 ring-forming carbons.

The electron transport region ETR may include an anthracene-based compound. However, embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzimidazol-1-yl)phenyl)-9,10-dinaphthylanthracene, 1,3,5-tri (1-phenyl-1H-benz[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq2), 9,10-di(naphthalene-2-yl) anthracene (ADN), 1,3-bis[3,5-di(pyridin-3-yl)phenyl]benzene (BmPyPhB), and a mixture thereof.

The electron transport region ETR may contain at least one among Compounds ET1 to ET38 below.

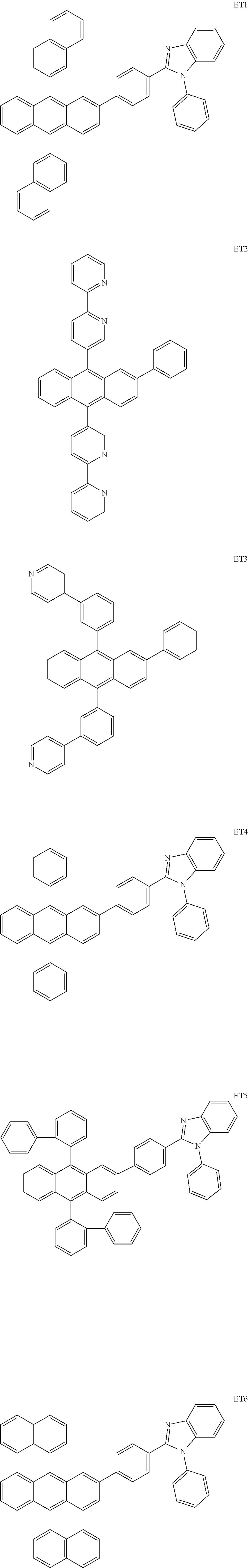

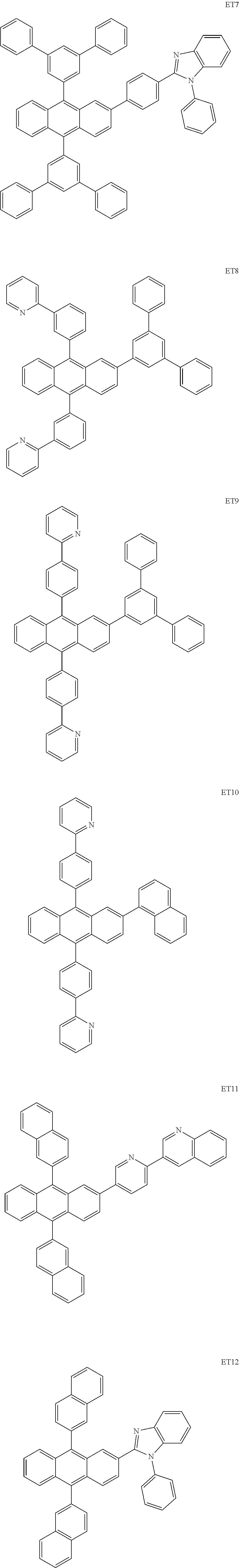

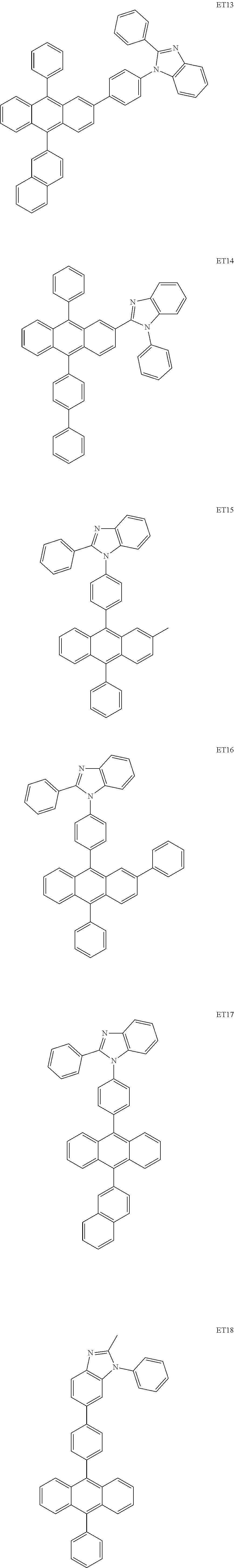 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

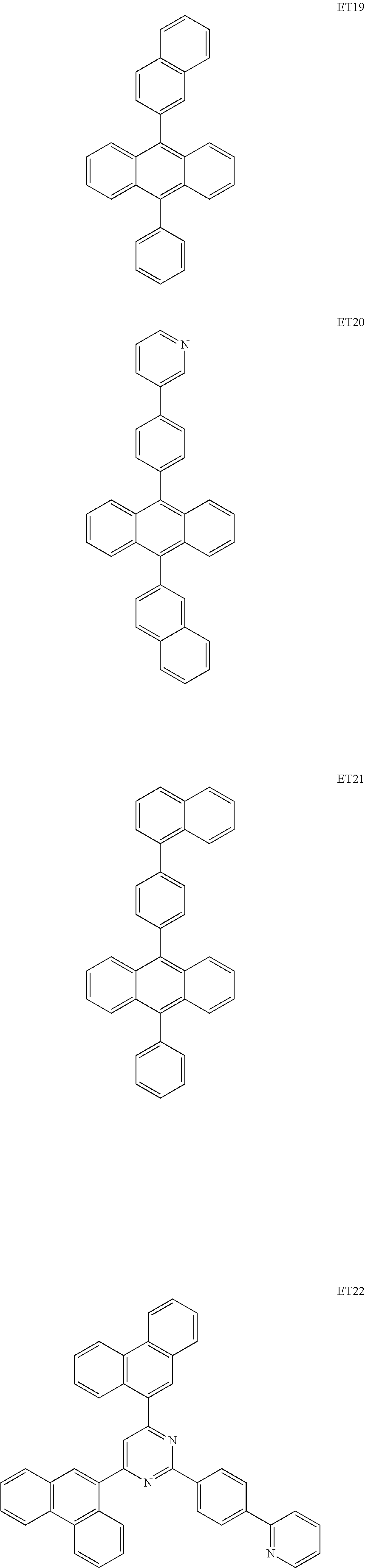

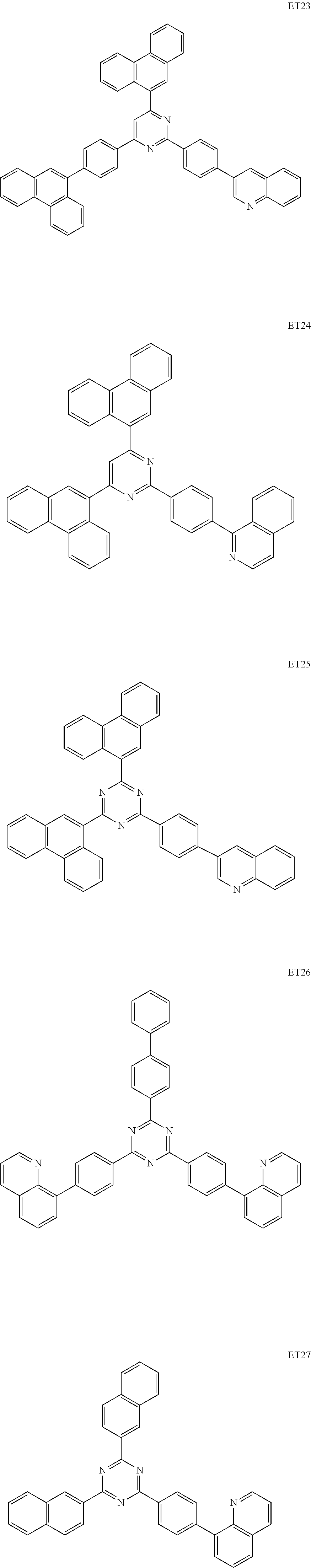 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

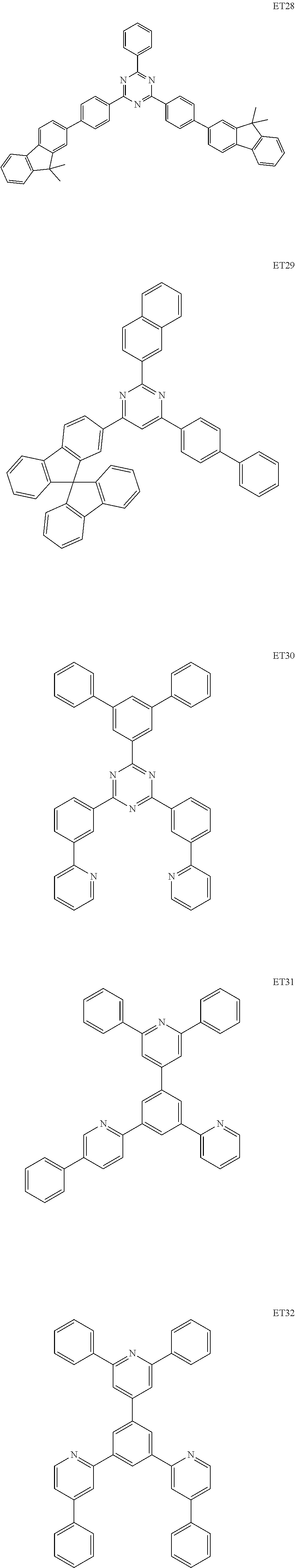 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

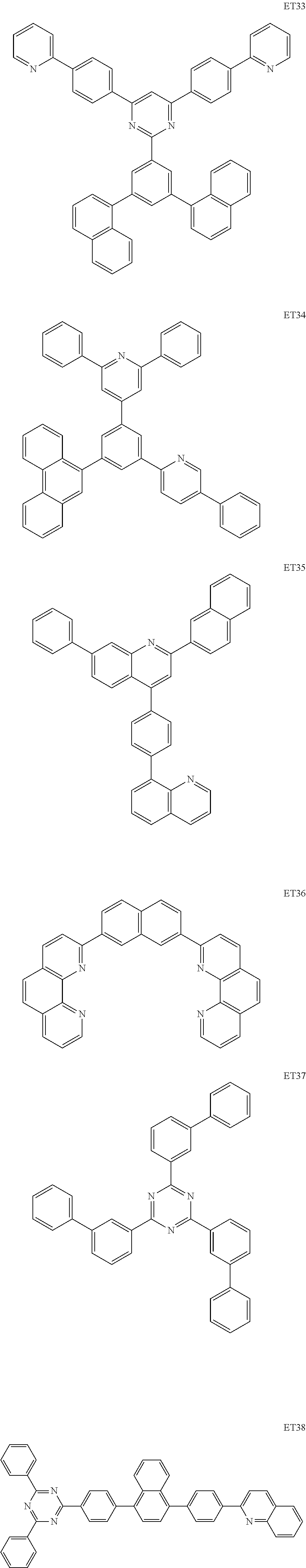 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; c1ccc(-c2cccc(-c3nc(-c4cccc(-c5ccccc5)c4)nc(-c4cccc(-c5ccccc5)c4)n3)c2)cc1 ; c1ccc(-c2nc(-c3ccccc3)nc(-c3ccc(-c4ccc(-c5ccc(-c6ccc7ccccc7n6)cc5)c5ccccc45)cc3)n2)cc1]

In some aspects, the electron transport region ETR may include a metal halide such as, for example, LiF, NaCl, CsF, RbCl, RbI, CuI and KI, a metal in lanthanoids such as, for example, Yb, or a co-depositing material of the metal halide and the metal in lanthanoides. For example, the electron transport layer ETL may include the metal halide such as, for example, LiF, NaCl, CsF, RbCl, RbI, CuI, and KI, the metal in lanthanoids such as, for example, Yb, or the co-depositing material of the metal halide and the metal in lanthanoids. The electron transport layer ETL may include KI:Yb, RbI:Yb, etc., as the co-depositing material. In some embodiments, the electron transport layer ETL may use: a metal oxide such as, for example, Li₂O and BaO; or 8-hydroxy-lithium quinolate (Liq). However, embodiments of the present disclosure are not limited thereto. The electron transport layer ETL may be formed using a mixture material of an electron transport material and an insulating organo metal salt. The organo metal salt may be a material having an energy band gap of about 4 eV or more. Particularly, the organo metal salt may include, for example, metal acetates, metal benzoates, metal acetoacetates, metal acetylacetonates, or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the above-described materials. However, embodiments of the present disclosure are not limited thereto.

Referring to FIG. 9B, the second light-emitting element NPE may include a first electrode NAE, a second hole transport region NHTR, a second emission layer NEL, an electron transport region ETR, and a second electrode CE.

The second hole transport region NHTR is provided on the first electrode WAE in the second region A2. The second hole transport region NHTR may include a hole injection layer HIL and a second hole transport layer NHTL. The same descriptions as in the first hole transport region WHTR may be similarly applied to materials included in the second hole transport region NHTR, a stacking structure of the second hole transport region NHTR, etc.

The second emission layer NEL may be provided on the second hole transport region NHTR in the second region A2, and the electron transport region ETR may be provided on the second emission layer NEL. The same descriptions as in the first emission layer WEL may be similarly applied to materials included in the second emission layer NEL, a stacking structure of the second emission layer NEL, etc.

Referring to FIG. 9A and FIG. 9B, the first light-emitting element WPE overlapping the first region A1 includes the first hole transport layer WHTL, and the second light-emitting element NPE overlapping the second region A2 includes the second hole transport layer NHTL. The first hole transport layer WHTL and the second hole transport layer NHTL may include the same material.

A (1-1)-st thickness (T_{W1}) of the first hole transport layer WHTL and a (2-1)-st thickness (T_{N1}) of the second hole transport layer NHTL may each range from about 30 Å to about 1000 Å. The (1-1)-st thickness (T_{W1}) of the first hole transport layer WHTL may be different from the (2-1)-st thickness (T_{N1}) of the second hole transport layer NHTL. The (1-1)-st thickness (T_{W1}) of the first hole transport layer WHTL may be smaller than the (2-1)-st thickness (T_{N1}) of the second hole transport layer NHTL. For example, the (1-1)-st thickness (T_{W1}) of the first hole transport layer WHTL may range from about 200 Å to about 1000 Å, the (2-1)-st thickness (T_{N1}) of the second hole transport layer NHTL may range from about 100 Å to about 800 Å. A first thickness difference (T_{N1}-T_{W1}) between the (1-1)-st thickness (T_{W1}) of the first hole transport layer WHTL and the (2-1)-st thickness (T_{N1}) of the second hole transport layer NHTL may range from about 30 Å to about 300 Å. For example, the first thickness difference (T_{N1}-T_{W1}) between the (1-1)-st thickness (T_{W1}) of the first hole transport layer WHTL and the (2-1)-st thickness (T_{N1}) of the second hole transport layer NHTL may range from about 50 Å to about 200 Å.

The first hole transport layer WHTL and the second hole transport layer NHTL may be formed via different processes. In an example in which the first hole transport layer WHTL and the second hole transport layer NHTL are formed using vacuum deposition, the first hole transport layer WHTL may be formed to have a (1-1)-st thickness (T_{W1}) using a first vacuum chamber, and the second hole transport layer NHTL may be formed to have a (2-1)-st thickness (T_{N1}) using a second vacuum chamber. Alternatively, the first hole transport layer WHTL and the second hole transport layer NHTL may be formed by a method in which after formation of the first hole transport layer WHTL and the second hole transport layer NHTL to have the (1-1)-st thickness (T_{W1}) using the (1-1)-st vacuum chamber, only the second hole transport layer NHTL is further formed by the first thickness difference (T_{N1}-T_{W1}) using the (2-1)-st vacuum chamber.

The first light-emitting element WPE overlapping the first region A1 and the second light-emitting element NPE overlapping the second region A2 may emit light with same color. The first light-emitting element WPE overlapping the first region A1 and the second light-emitting element NPE overlapping the second region A2 may include the same materials.

A (1-2)-nd thickness (T_{W2}) of the first emission layer WEL and a (2-2)-nd thickness (T_{N2}) of the second emission layer NEL may each range from about 100 Å to about 1000 Å. The (1-2)-nd thickness (T_{W2}) of the first emission layer WEL is different from the (2-2)-nd thickness (T_{N2}) of the second emission layer NEL. The (1-2)-nd thickness (T_{W2}) of the first emission layer WEL is larger than the (2-2)-nd thickness (T_{N2}) of the second emission layer NEL. For example, the (1-2)-nd thickness (T_{W2}) of the first emission layer WEL may range from about 100 Å to about 800 Å, and the (2-2)-nd thickness (T_{N2}) of the second emission layer NEL may range from about 200 Å to about 1000 Å. A second thickness difference (T_{W2}-T_{N2}) between the (1-2)-nd thickness (T_{W2}) of the first emission layer WEL and the (2-2)-nd thickness (T_{N2}) of the second emission layer NEL may range from about 30 Å to about 300 Å.

The first emission layer WEL and the second emission layer NEL may be formed by different processes from each other. If the first emission layer WEL and the second emission layer NEL are formed using a vacuum deposition method, the first emission layer NEL may be formed using a third vacuum chamber to have a (2-1)-st thickness (T_{W2}), and the second emission layer WEL may be formed using a fourth vacuum chamber to have a (2-2)-nd thickness (T_{N2}). Alternatively, the first emission layer NEL and the second emission layer WEL are formed by a method in which after formation of the first emission layer WEL and the second emission layer NEL to have the (1-1)-st thickness (T_{W1}) using a (3-1)-st vacuum chamber, only the second emission layer NEL is further formed by the second thickness difference (T_{w2}-Tₙ₂) using a (4-1)-st vacuum chamber.

The first thickness difference (T_{N1}-T_{W1}) and the second thickness difference (T_{W2}-T_{N2}) may be substantially the same. That is, as the (2-1)-st thickness (T_{N1}) of the second hole transport layer NHTL is larger than the (1-1)-st thickness (T_{W1}) of the hole transport layer WHTL, the (1-2)-nd thickness (T_{W2}) of the first emission layer WEL may be larger than the (2-2)-nd thickness (T_{N2}) of the second emission layer NEL. Therefore, in the first emission layer WPE overlapping the first region A1, the sum of the thickness of the first hole transport layer NHTL and the thickness of the first emission layer WEL may be substantially the same as the sum of the thickness of the second hole transport layer NHTL and the thickness of the second emission layer NEL in the second light-emitting element NPE. In an example in which the sum of the (1-1)-st thickness (T_{W1}) of the first hole transport layer WHTL and the (1-2)-nd thickness (T_{W2}) of the first emission layer WEL is defined as a (3-1)-st thickness (T_{WS}) and the sum of the (2-1)-st thickness (T_{N1}) of the second hole transport layer NHTL and the (2-2)-nd thickness (T_{N2}) of the second emission layer NEL is defined as a (3-2)-nd thickness (T_{NS}), a third thickness difference (T_{WS}-T_{NS}) may 0. Therefore, even though there are a thickness difference between the first and second hole transport layers WHTL and NHTL and a thickness difference between the first and second emission layers WEL and NEL, an optical resonance distance between the first electrode WAE and the electron transport region ETR in the first light-emitting element WPE may be substantially the same as an optical resonance distance between the first electrode NAE and the electron transport region ETR in the second light-emitting element NPE.

In a case of the light-emitting element according to an embodiment of the inventive concept, compared to a case of the first light-emitting element overlapping the first region, the hole transport layer included in the second light-emitting element overlapping the second region is relatively thick. Therefore, in a case of the second light-emitting element, a hole injection barrier for injected holes from the first electrode for reaching an emission layer may be relatively lowered, which may make charges easily injected. Activation of the second pixel group including the second light-emitting element may be implemented with a relatively low driving voltage. As described herein, in cases of the display module according to an embodiment of the inventive concept and the electron device including the display module, both the first pixel group and the second pixel group are activated in the first mode, which is a normal mode, and only the second pixel mode is activated in the second mode, which is a private mode. However, in the second region where the second pixel group is activated, since the first light-blocking layer where the first opening having a relatively small area is defined, is disposed, and the second light-blocking layer is additionally disposed, there is a limitation in that more current may be required, compared to the first pixel group. However, since the second pixel group according to an embodiment of the inventive concept includes the second light-emitting element, the limitation of the driving voltage may be solved. In the cases of the display module according to an embodiment of the inventive concept and the electronic device including the display module, a low driving voltage under a certain level may be secured, and thus the module and the device having improved reliability may be provided even in the second mode, which is a private mode.

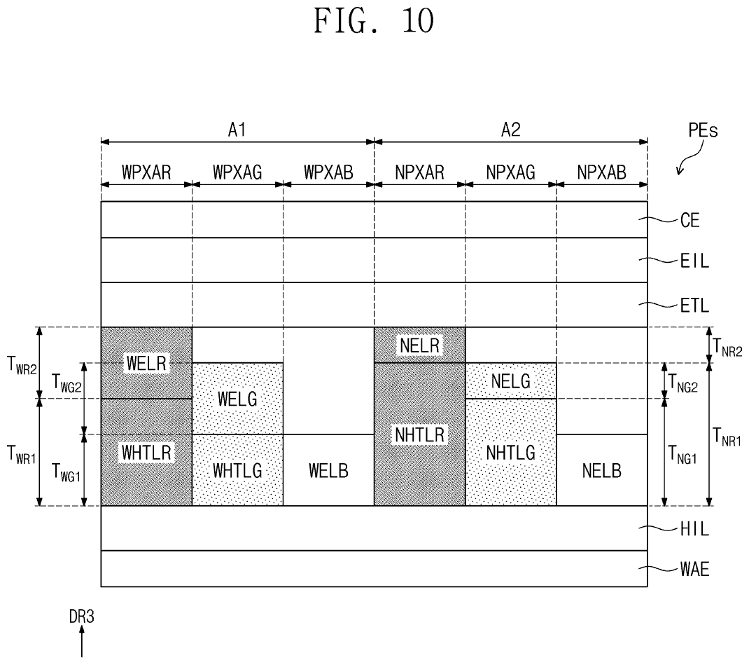

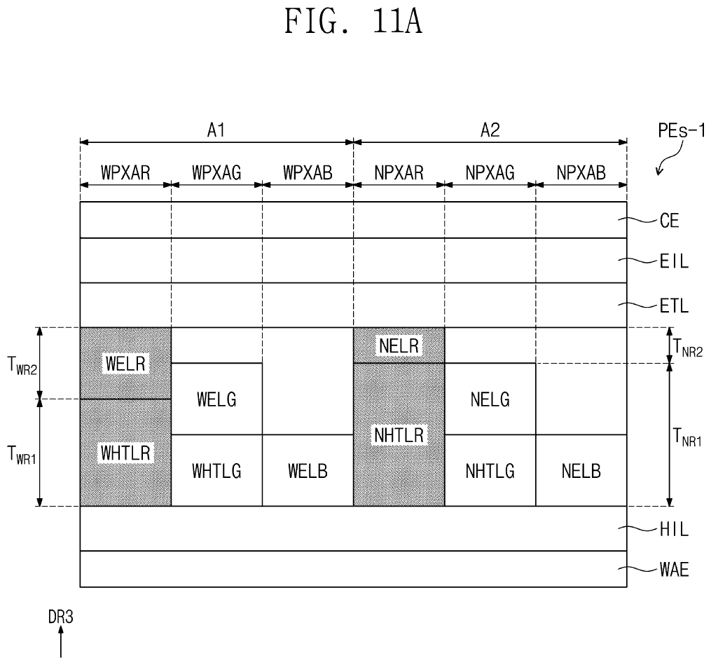

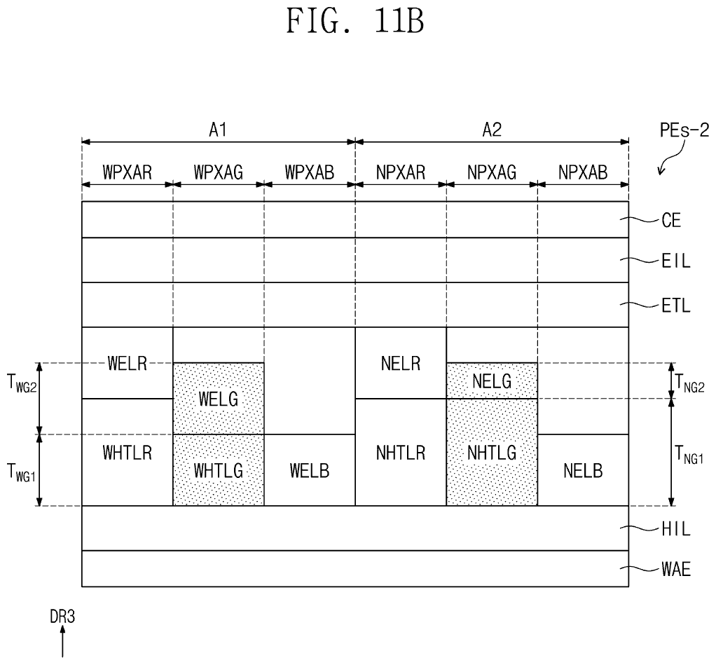

FIG. 10 schematically illustrates the light-emitting elements according to an embodiment of the inventive concept. FIG. 10 schematically illustrates a shape in which the first light-emitting element WPE (see FIG. 9A) overlapping the first region A1 are provided in plurality, and the second light-emitting element NPE (see FIG. 9B) overlapping the second region A2 are provided in plurality. FIG. 10 illustrates that, in the light-emitting elements PE, no separate region exist between the (1-1)-st to (1-3)-rd pixel regions WPXAR, WPXAG, and WPXAB, and between the first region A1 and the second region A2. However, this is illustrated for convenience for illustrative purposes, but embodiments of the present disclosure are not limited thereto. FIG. 11A and FIG. 11B are each a cross-sectional view schematically illustrating the light-emitting elements according to another embodiment of the inventive concept. FIG. 11A and FIG. 11B illustrates another embodiment of the light-emitting elements PEs-1 and PEs-2 corresponding to FIG. 10. In some embodiments, for configurations identical/similar as the configurations described in FIG. 4 to FIG. 9B, the identical/similar reference numerals are used and the duplicated descriptions are omitted.

Referring to FIG. 10, FIG. 11A and FIG. 11B, the first hole transport layers WHTLR and WHTLG may include a (1-1)-st hole transport layer WHTLR overlapping the (1-1)-st pixel region WPXAR, and a (1-2)-nd hole transport layer WHTLG overlapping the (1-2)-nd pixel region WPXAG. In an embodiment, the first hole transport layers WHTLR and WHTLG may not overlap a (1-3)-rd pixel region WPXAB, and the (1-3)-rd emission layer WELB may directly receive holes from the hole injection layer HIL, but embodiments of the present disclosure are not limited thereto.

The second hole transport layers NHTLR and NHTLG may include a (2-1)-st hole transport layer NHTLR overlapping the (2-1)-st pixel region NPXAR, and a (2-2)-nd hole transport layer NHTLG overlapping the (2-2)-nd pixel region NPXAG. In an embodiment, the second hole transport layers NHTLR and NHTLG may not overlap a (1-3) pixel region WPXAB and a (2-3)-rd emission layer NEBL may directly receive holes injected from the hole injection layer HIL, but embodiments of the present disclosure are not limited thereto.

A (1-1)-st thickness (T_{WR1}) of the (1-1)-st hole transport layer WHTLR may be smaller than a (2-1)-st thickness (T_{NR1}) of the (2-1)-st hole transport layer NHTLR. For example, the (1-1)-st thickness (T_{WR1}) of the (1-1)-st hole transport layer WHTLR may range from about 500 Å to about 800 Å, and the (2-1)-st thickness (T_{NR1}) of the (2-1)-st hole transport layer NHTLR may range from about 700 Å to about 1000 Å. A first thickness difference (T_{NR1}-T_{WR1}) between the (1-1)-st thickness (T_{WR1}) of the (1-1)-st hole transport layer WHTLR and the (2-1)-st thickness (T_{NR1}) of the (2-1)-st hole transport layer NHTLR may range from about 100 Å to about 300 Å.

A (1-1)-st thickness (T_{WG1}) of the (1-2)-nd hole transport layer WHTLG may be smaller than a (2-1)-st thickness (T_{NG1}) of the (2-2)-nd hole transport layer NHTLG. For example, the (1-1)-st thickness (T_{WG1}) of the (1-2)-nd hole transport layer WHTLG may range from about 100 Å to about 400 Å, and the (2-1)-st thickness (T_{NG1}) of the (2-2)-nd hole transport layer NHTLG may range from about 200 Å to about 600 Å. A first thickness difference (T_{NG1}-T_{WG1}) between the (1-1)-st thickness (T_{WG1}) of the (1-2)-nd hole transport layer WHTLG and the (2-1)-st thickness (T_{NG1}) of the (2-2)-nd hole transport layer NHTLG may range from about 50 Å to about 200 Å.

The first emission layer WELR, WELG, and WELB may include a (1-1)-st emission layer WELR overlapping the (1-1)-st pixel region WPXAR, a (1-2)-nd emission layer WELG overlapping the (1-2)-nd pixel region WPXAG, and a (1-3)-rd emission layer WELB overlapping the (1-3)-rd pixel region WPXAB. The second emission layer NELR, NELG, and NELB may include a (2-1)-st emission layer NELR overlapping the (2-1)-st pixel region NPXAR, a (2-2)-nd emission layer NELG overlapping the (2-2)-nd pixel region NPXAG, and a (2-3)-rd emission layer NELB overlapping the (2-3)-rd pixel region NPXAB.

A (1-2)-nd thickness (T_{WR2}) of the (1-1)-st emission layer WELR may be smaller than a (2-2)-nd thickness (T_{NR2}) of the (2-1)-st emission layer NELR. For example, the (1-2)-nd thickness (T_{WR2}) of the (1-1)-st emission layer WELR may range from about 300 Å to about 600 Å, and the (2-2)-nd thickness (T_{NR2}) of the (2-1)-st emission layer NELR may range from about 10 Å to about 500 Å. A second thickness difference (T_{WR2}-T_{NR2}) between the (1-2)-nd thickness (T_{WR2}) of the (1-1)-st emission layer WELR and the (2-2)-nd thickness (T_{NR2}) of the (2-1)-st emission layer NELG may range from about 100 Å to about 300 Å.

A (1-2)-nd thickness (T_{WG2}) of the (1-2)-nd emission layer WELG may be smaller than a (2-2)-nd thickness (T_{NG2}) of the (2-2)-st emission layer NELG. For example, the (1-2)-nd thickness (T_{WG2}) of the (1-2)-nd emission layer WELG may range from about 200 Å to about 600 Å, and the (2-1)-nd thickness (T_{NG2}) of the (1-2)-nd emission layer NELG may range from about 100 Å to about 400 Å. A second thickness difference (T_{WG2}-T_{NG2}) between the (1-2)-nd thickness (T_{WG2}) of the (1-2)-nd emission layer WELG and the (2-1)-nd thickness (T_{NG2}) of the (2-2)-st emission layer NELG may range from about 100 Å to about 300 Å.

Hereinafter, the evaluation results of characteristics of the display module according to an embodiment of the inventive concept will be described with reference to the above-described FIG. 6A, FIG. 6B, and FIG. 10, and examples and comparative examples below. In some aspects, the embodiments below are illustrations to assist the understanding of the inventive concept, and the scope of the inventive concept is not limited thereto.

### (Manufacture of Display Module)

The display module according to Example 1 to Example 3, and Comparative Example 1 were manufactured to have a stacking structure of the display module illustrated in FIG. 6A and FIG. 6B. In each of the display modules according to Example 1 to Example 3, and Comparative Example 1, a thickness (T_{WR1}) of the (1-1)-st hole transport layer WHTLR and a thickness of (T_{WR2}) of the (1-1)-st emission layer WELR, each overlapping the (1-1)-st pixel region WPXAR, and a thickness (T_{NR1}) of the (2-1)-st hole transport layer NHTLR and a thickness (T_{NR2}) of the (2-1)-st emission layer NELR, each overlapping the (2-1)-st pixel region WPXAR, are listed in Table 1 below, and, based on these values, the first thickness difference (T_{NR1}-T_{WR1}), the second thickness difference (T_{WR2}-T_{NR2}), and the third thickness difference (T_{WS}-T_{NS}) are calculated. In each of the display modules according to Example 1 to Example 3, and Comparative Example 1, a thickness (T_{WG1}) of the (1-2)-nd hole transport layer WHTLG and a thickness (T_{WG2}) of the (1-2)-nd emission layer WELG, each overlapping the (1-2)-nd pixel region WPXAG, and a thickness (T_{NG1}) of the (2-2)-nd hole transport layer NHTLG and a thickness (T_{NG2}) of the (2-2)-nd emission layer NELG, each overlapping the (2-2)-nd pixel region NPXAG are listed in Table 2 below, and, based on these values, the first thickness difference (T_{NG1}-T_{WG1}), the second thickness difference (T_{WG2}-T_{NG2}), and the third thickness difference (T_{WS}-T_{NS}) are calculated. The display modules according to Example 1 to Example 3, and Comparative Example 1 were manufactured in the same manner except for the first to third thickness differences.

TABLE 1

| | Thickness of HTR | | Thickness of EL | | | | |
|---|---|---|---|---|---|---|---|
| | (T_{WR1}, T_{NR1}, Å) | | (T_{WR2}, T_{NR2}, Å) | | First | Second | Third |
| | (1-1)-st pixel | (2-1)-st pixel | (1-1)-st pixel | (2-1)-st pixel | thickness | thickness | thickness |
| | region | region | region | region | difference | difference | difference |
| | (WPXAR) | (NPXAR) | (WPXAR) | (NPXAR) | (Å) | (Å) | (Å) |
| Example 1 | 780 | 930 | 400 | 250 | 150 | 150 | 0 |
| Example 2 | 780 | 910 | 400 | 270 | 130 | 130 | 0 |
| Example 3 | 780 | 950 | 400 | 230 | 170 | 170 | 0 |
| Comparative | 780 | 780 | 400 | 400 | 0 | 0 | 0 |
| Example 1 | | | | | | | |

TABLE 2

| | Thickness of HTR | | Thickness of EL | | | | |
|---|---|---|---|---|---|---|---|
| | (T_{WG1}, T_{NG1}, Å) | | (T_{WG2}, T_{NG2}, Å) | | First | Second | Third |
| | (1-2)-rd pixel | (2-2)-rd pixel | (1-2)-rd pixel | (2-2)-rd pixel | thickness | thickness | thickness |
| | region | region | region | region | difference | difference | difference |
| | (WPXAG) | (NPXAG) | (WPXAG) | (NPXAG) | (Å) | (Å) | (Å) |
| Example 1 | 270 | 350 | 380 | 300 | 80 | 80 | 0 |
| Example 2 | 270 | 330 | 380 | 320 | 60 | 60 | 0 |
| Example 3 | 270 | 370 | 380 | 280 | 100 | 100 | 0 |
| Comparative | 270 | 270 | 380 | 380 | 0 | 0 | 0 |
| Example 1 | | | | | | | |

### (Evaluation of Characteristics of Display Module)

Evaluation results in characteristics of the display modules according to examples and comparative examples are listed in Table 3 below. For the evaluation of characteristics of the display modules in Table 3, each emission efficiency of the display modules according to Example 1 to Example 3 in the (2-1)-st pixel region NPXAR and the (2-2)-nd pixel region NPXAG was measured and the measured value was relatively expressed as a percentage (%) as the relative emission efficiency (%) based on measured emission efficiency of the display module according to Comparative Example 1. In some aspects, each driving voltage of the display modules according to Example 1 to Example 3 was measured and the measured value was relatively expressed as a percentage (%) as the relative driving voltage (%) in the (2-1)-st pixel region NPXAR and the (2-2)-st pixel region NPXAG based on a measured driving voltage of the display module according to Comparative Example 1.

TABLE 3

| | |
|---|---|
| (2-1)-st pixel region | (2-2)-nd pixel region |
| (NPXAR) | (NPXAG) |

| | Relative | Relative | Relative | Relative |
|---|---|---|---|---|
| | emission | driving | emission | driving |
| | efficiency | voltage | efficiency | voltage |
| | (%) | (%) | (%) | (%) |
| Example 1 | 100 | 92.6 | 100 | 93.7 |
| Example 2 | 100 | 94.1 | 100 | 94.5 |
| Example 3 | 99 | 92.6 | 98 | 90.6 |
| Comparative | 100 | 100 | 100 | 100 |
| Example 1 | | | | |

Referring to results in Table. 3, compared to the display module according to Comparative Example 1, it can be confirmed that the display modules according to examples maintain emission efficiency in the (2-1)-st pixel region NPXAR and the (2-2)-nd pixel region NPXAG, and simultaneously have a lowered driving voltage. In the display module according to an embodiment of the inventive concept and the electronic device including the display module, since the hole transport layer overlapping the (2-1)-st pixel region NPXAR and the (2-2)-nd pixel region NPXAG, that is, overlapping the second region, is relatively thick, a low driving voltage under a certain level may be secured even in the second mode, which is a private mode, and thus the module and device having improved reliability may be provided.

According to the inventive concept, the display module includes a light-emitting element in which a thickness of the hole transport layer is different from each other, and thus may be driven with a low consumption power even when light emitted at high angle from a screen having a different viewing angle. Therefore, the display module having improved display quality and reliability and the electronic device including the display module may be provided.

Hither to, although the embodiments of the present invention have been described with reference to preferable embodiments, it is understood that various changes and modifications can be made by one ordinary skilled in the art within the spirit and scope of the present invention as hereinafter claimed.

Accordingly, the technical scope of the inventive concept is not limited to the contents set forth in the detailed description of the specification, but is defined by the appended claims.

What is claimed is:

1. A display module comprising:
a display panel comprising:
a first light-emitting element which overlaps a first pixel region and emits light of a first color; and
a second light-emitting element which overlaps a second pixel region that is spaced apart from the first pixel region on a plane and emits the light of the first color;
an anti-reflection layer disposed on the display panel and comprising a first light-blocking layer; and
an optical functional layer disposed on the anti-reflection layer and comprising a second light-blocking layer,
wherein:
first openings corresponding to the first pixel region and the second pixel region are defined in the first light-blocking layer,
second openings overlapping the first pixel region and the second pixel region and corresponding to the first openings are defined in the second light-blocking layer,
the first light-emitting element comprises a first hole transport layer and a first emission layer disposed on the first hole transport layer,
the second light-emitting element comprises a second hole transport layer and a second emission layer disposed on the second hole transport layer, and
the first hole transport layer has a (1-1)-st thickness smaller than a (2-1)-st thickness of the second hole transport layer.

2. The display module of claim 1, wherein the second light-blocking layer does not overlap the first pixel region.

3. The display module of claim 1, wherein the first emission layer has a (1-2)-nd thickness greater than a (2-2)-nd thickness of the second emission layer.

4. The display module of claim 3, wherein a sum of the (1-1)-st thickness and the (1-2)-nd thickness is substantially equal to a sum of the (2-1)-st thickness and the (2-2)-nd thickness.

5. The display module of claim 1, wherein a material comprised in the first hole transport layer is the same as a material comprised in the second hole transport layer.

6. The display module of claim 1, wherein a material comprised in the first emission layer is the same as a material comprised in the second emission layer.

7. The display module of claim 1, wherein:
the display panel further comprises a pixel definition film in which a plurality of pixel openings corresponding to the first pixel region and the second pixel region is defined, and
each of the first emission layer and the second emission layer is disposed in each of the plurality of pixel openings.

8. The display module of claim 1, wherein:
the anti-reflection layer further comprises a plurality of color filters corresponding to the first pixel region and the second pixel region, and
the first light-blocking layer separates the plurality of color filters from one another.

9. The display module of claim 1, wherein the optical functional layer further comprises an over-coating layer covering the second light-blocking layer.

10. The display module of claim 1, wherein:
the first light-emitting element and the second light-emitting element are driven in a first mode, and
the first light-emitting element is not driven, and the second light-emitting element is driven, in a second mode having low reflectance compared to the first mode.

11. The display module of claim 1, wherein the light of the first color is red light or green light.

12. The display module of claim 1, further comprising a sensor layer between the display panel and the anti-reflection layer.

13. A display module comprising:
a first pixel group comprising a first light-emitting element that emits light of a first color and overlaps a first region; and
a second pixel group comprising a second light-emitting element that emits the light of the first color and overlaps a second region that has a lower light transmittance for the light of the first color than the first region,
wherein:
the light of the first color is red light or green light,
the first light-emitting element comprises a first hole transport layer and a first emission layer that is disposed on the first hole transport layer,
the second light-emitting element comprises a second hole transport layer and a second emission layer that is disposed on the second hole transport layer, and
a (1-1)-st thickness of the first hole transport layer is smaller than a (2-1)-st thickness of the second hole transport layer.

14. The display module of claim 13, wherein a first thickness difference between the (2-1)-st thickness of the second hole transport layer and the (1-1)-st thickness of the first hole transport layer ranges from about 30 Å to about 300 Å.

15. The display module of claim 13, wherein:
the first region comprises a (1-1)-st pixel region which emits red light, a (1-2)-nd pixel region which emits green light, and a (1-3)-rd pixel region which emits blue light, and
the second region comprises a (2-1)-st pixel region which emits red light, a (2-2)-nd pixel region which emits green light, and a (2-3)-rd pixel region which emits blue light.

16. The display module of claim 15, wherein:
an area of the (1-1)-st pixel region on a plane is relatively larger than an area of the (2-1)-st pixel region on the plane;
an area of the (1-2)-nd pixel region on the plane is relatively larger than an area of the (2-2)-nd pixel region on the plane; and
an area of the (1-3)-rd pixel region on the plane is relatively larger than an area of the (2-3)-rd pixel region on the plane.

17. The display module of claim 15, wherein:
the first hole transport layer and the first emission layer are each disposed corresponding to the (1-1)-st pixel region, and
the second hole transport layer and the second emission layer are each disposed corresponding to the (2-1)-st pixel region.

18. The display module of claim 15, further comprising:
a hole injection layer disposed below the first hole transport layer and the second hole transport layer,
wherein the hole injection layer is commonly disposed in the (1-1)-st pixel region, the (1-2)-nd pixel region, and the (1-3)-rd pixel region.

19. The display module of claim 18, wherein the hole injection layer comprises a charge generating material.

20. An electronic device comprising:
a display module;
a window disposed on the display module; and
a housing combined with the window and accommodating the display module,
wherein the display module comprises:
a display panel comprising:
a first light-emitting element that overlaps a first pixel region and emits light of a first color, and
a second light-emitting element that overlaps a second pixel region spacing apart from the first pixel region on a plane and emits the light of the first color;
an anti-reflection layer disposed on the display panel and comprising a first light-blocking layer; and
an optical functional layer disposed on the anti-reflection layer and comprising a second light-blocking layer,
wherein:
first openings corresponding to the first pixel region and the second pixel region are defined in the first light-blocking layer,
second openings overlapping the first pixel region and the second pixel region and corresponding to the first openings are defined in the second light-blocking layer,
the first light-emitting element comprises a first hole transport layer and a first emission layer disposed on the first hole transport layer,
the second light-emitting element comprises a second hole transport layer and a second emission layer disposed on the second hole transport layer, and
a (1-1)-st thickness of the hole transport layer is smaller than a (2-1)-st thickness of the second hole transport layer.
